(19) United States
(12) Patent Application Publication
(10) Pub. No.: US 2024/0349547 A1
(43) Pub. Date: Oct. 17, 2024

(54) DISPLAY DEVICE AND METHOD OF MANUFACTURING THE SAME

(71) Applicants: Samsung Display Co., Ltd., Yongin-Si (KR); IUCF-HYU (Industry-University Cooperation Foundation Hanyang University), Seoul (KR)

(72) Inventors: EUN HYUN KIM, Yongin-si (KR); Gwang Bok KIM, Seoul (KR); JUN HYUNG LIM, Yongin-si (KR); Jae Kyeong JEONG, Seoul (KR)

(21) Appl. No.: 18/619,160

(22) Filed: Mar. 28, 2024

(30) Foreign Application Priority Data
Apr. 12, 2023 (KR) 10-2023-0048246

(51) Int. Cl. H10K 59/124; H01L 29/24; H01L 29/786; H10K 59/12

(52) U.S. Cl. CPC H10K 59/124; H01L 29/24; H01L 29/7869; H10K 59/1201

(57) ABSTRACT

A display device is disclosed that includes a base substrate, an organic light emitting element disposed on the base substrate, an insulating layer disposed on the base substrate and containing silicon oxide, and a thin film transistor disposed on the base substrate and electrically connected to the organic light emitting element, wherein the thin film transistor includes a semiconductor pattern disposed on the base substrate and including a channel area in contact with the insulating layer, and a gate electrode overlapping the channel area on a plane, wherein the semiconductor pattern contains indium gallium zinc tin oxide.

### CROSS-REFERENCE TO RELATED APPLICATIONS

This application claims priority under 35 U.S.C. § 119 to Korean Patent Application No. 10-2023-0048246 filed on Apr. 12, 2023, in the Korean Intellectual Property Office, the disclosures of which are incorporated by reference herein in their entireties.

### BACKGROUND

Embodiments of the present disclosure described herein relate to a display device and a method of manufacturing the same, and more particularly, relate to a display device including an oxide transistor and a method of manufacturing the same.

A display device includes a display panel, and the display panel includes a light emitting element and a pixel circuit for controlling an electrical signal applied to the light emitting element. The pixel circuit may include at least two transistors. As a high-resolution display panel is developed, a design of the transistors is limited.

### SUMMARY

Embodiments of the present disclosure may provide a high-resolution display panel.

Embodiments of the present disclosure may provide a method of manufacturing a high-resolution display panel.

An embodiment of a display device includes a base substrate, an organic light emitting element disposed on the base substrate, an insulating layer disposed on the base substrate and containing silicon oxide, and a thin film transistor disposed on the base substrate and electrically connected to the organic light emitting element, the thin film transistor includes a semiconductor pattern disposed on the base substrate and including a channel area in contact with the insulating layer, and a gate electrode overlapping the channel area on a plane, the semiconductor pattern includes indium (In) gallium (Ga) zinc (Zn) tin (Sn) oxide, and a ratio of tin in the channel area is equal to or higher than about 10%.

In an embodiment, the channel area may have a composition ratio of In:Ga:Zn:Sn=29.4:39.8:12.6:18.2 (at. %).

In an embodiment, the insulating layer may contain at least a portion of a DIPAS precursor.

In an embodiment, the semiconductor pattern may be disposed on the gate electrode.

In an embodiment, the gate electrode may be disposed on the semiconductor pattern, and the insulating layer may be disposed between the gate electrode and the semiconductor pattern.

In an embodiment, a thickness of the insulating layer may be greater than 5 nm and smaller than 20 nm.

In an embodiment, a thickness of the insulating layer may be smaller than 10 nm.

In an embodiment, the channel area of the semiconductor pattern may have saturation mobility equal to or greater than about 30 cm²/Vs.

In an embodiment, the insulating layer may contain hydrogen atoms.

In an embodiment, the display device may further include a conductive pattern connected to a source area or a drain area.

An embodiment of a method of manufacturing a display device includes forming a gate electrode, forming a semiconductor pattern including indium (In) gallium (Ga) zinc (Zn) tin (Sn) oxide obtained from indium gallium zinc oxide and tin oxide, forming an insulating layer containing silicon oxide, and forming an organic light emitting element on the insulating layer, the insulating layer is in contact with the semiconductor pattern, the forming of the insulating layer uses a PEALD scheme using a DIPAS precursor.

In an embodiment, the insulating layer may be formed after the forming of the semiconductor pattern.

In an embodiment, mobility of the semiconductor pattern may increase after the insulating layer is formed.

In an embodiment, the semiconductor pattern may be formed after the forming of the gate electrode.

In an embodiment, the indium gallium zinc oxide may have a composition ratio of In:Ga:Zn=1:1:1.

In an embodiment, the indium gallium zinc tin oxide may have a composition ratio of In:Ga:Zn:Sn=29.4:39.8:12.6:18.2 (at. %).

In an embodiment, the method may further include heat-treating the insulating layer after the semiconductor pattern and the insulating layer are formed, and a heat treatment temperature may be higher than 300° C. and lower than 500° C.

In an embodiment, the heat treatment temperature may be about 400° C.

In an embodiment, the insulating layer may contain at least a portion of the DIPAS precursor.

In an embodiment, a concentration of hydrogen atoms at an interface of the insulating layer in contact with the semiconductor pattern may be reduced after the heat-treating of the insulating layer.

### BRIEF DESCRIPTION OF THE FIGURES

The above and other objects and features of the present disclosure will become apparent by describing in detail embodiments thereof with reference to the accompanying drawings.

FIG. 1 is a block diagram of a display device according to an embodiment of the present disclosure.

FIG. 2 is an equivalent circuit diagram of a pixel according to an embodiment of the present disclosure.

FIG. 3 is a timing diagram of driving signals for driving a pixel shown in FIG. 2.

FIG. 4 is a cross-sectional view of a display panel according to an embodiment of the present disclosure.

FIGS. 5A, 5B, and 5C are cross-sectional views of a transistor according to an embodiment of the present disclosure.

FIG. 6 is a block diagram illustrating a method of manufacturing a display panel according to an embodiment of the present disclosure.

FIGS. 7A, 7B, 7C, 7D, 7E, 7F, and 7G are cross-sectional views illustrating a method of manufacturing a display panel according to an embodiment of the present disclosure.

FIG. 8 is a cross-sectional view illustrating a method of manufacturing a display panel according to an embodiment of the present disclosure.

FIGS. 9A and 9B are graphs showing electrical characteristics of Present Example of the present disclosure and Comparative Examples.

FIGS. 10A, 10B, 10C, 10D, and 10E are graphs showing electrical characteristics of Present Example of the present disclosure and Comparative Examples.

FIGS. 11A, 11B, and 11C are graphs showing electrical characteristics of Present Example of the present disclosure and Comparative Examples.

FIGS. 12A and 12B are graphs comparing electrical characteristics of Present Example of the present disclosure and Comparative Examples.

FIGS. 13A, 13B, and 13C are graphs comparing electrical characteristics of Present Example of the present disclosure and Comparative Examples.

FIGS. 14A and 14B are graphs comparing electrical characteristics of Present Example of the present disclosure and Comparative Examples.

FIGS. 15A and 15B are graphs comparing electrical characteristics of Present Example of the present disclosure and Comparative Examples.

### DETAILED DESCRIPTION

In the present document, when a component (or an area, a layer, a portion, and the like) is referred to as being “on”, “connected to”, or “coupled to” another component, it means that the component may be directly disposed/connected/coupled on another component or a third component may be disposed between the component and another component.

Like reference numerals refer to like components. In addition, in the drawings, thicknesses, ratios, and dimensions of components are exaggerated for effective description of technical content.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

Terms such as first, second, and the like may be used to describe various components, but the components should not be limited by the terms. The above terms are used only for the purpose of distinguishing one component from another. For example, without departing from the scope of the present disclosure, a first component may be named as a second component, and similarly, the second component may also be named as the first component. The singular expression includes the plural expression unless the context clearly dictates otherwise.

In addition, terms such as “beneath”, “below”, “on”, “above” are used to describe the relationship of the components shown in the drawings. The above terms are relative concepts, and are described with reference to directions indicated in the drawings.

Unless otherwise defined, all terms including technical and scientific terms used herein have the same meaning as commonly understood by one of ordinary skill in the art to which this disclosure belongs. Terms, such as those defined in commonly used dictionaries, should be interpreted as having a meaning that is consistent with their meaning in the context of the relevant art and will not be interpreted in an idealized or overly formal sense unless expressly so defined herein.

It should be understood that terms such as “comprise,” “include,” and “have” are intended to specify that a feature, a number, a step, an operation, a component, a part, or a combination thereof described in the specification is present, and do not preclude a possibility of addition or existence of one or more other features or numbers, steps, operations, components, parts, or combinations thereof.

Hereinafter, embodiments of the present disclosure will be described with reference to drawings.

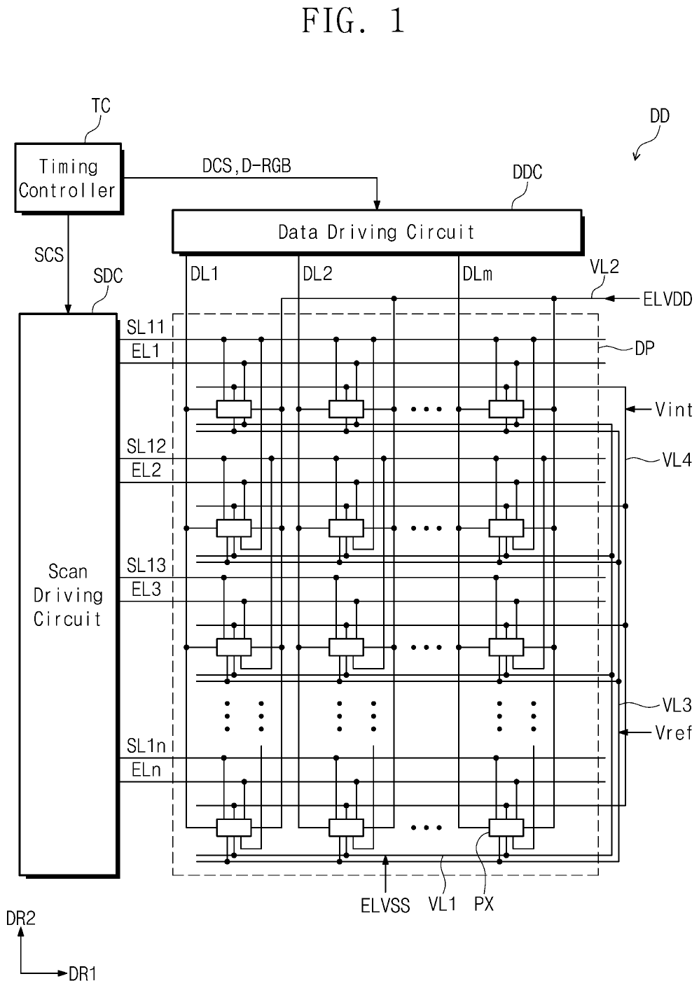

FIG. 1 is a block diagram of a display device DD according to an embodiment of the present disclosure. The display device DD includes a timing controller TC, a scan driving circuit SDC, a data driving circuit DDC, and a display panel DP. In the present embodiment, the display panel DP is described as a light emitting display panel. The light emitting display panel may include an organic light emitting display panel or an inorganic light emitting display panel.

The timing controller TC receives input image signals, converts data formats of the input image signals to meet specifications of an interface with the scan driving circuit SDC, and generates image data D-RGB. The timing controller TC outputs the image data D-RGB and various control signals DCS and SCS.

The scan driving circuit SDC receives the scan control signal SCS from the timing controller TC. The scan control signal SCS may include a vertical start signal for starting an operation of the scan driving circuit SDC, a clock signal for determining output timings of signals, and the like. The scan driving circuit SDC generates a plurality of scan signals and sequentially outputs the scan signals to scan signal lines SL11 to SL1n respectively corresponding thereto. In addition, the scan driving circuit SDC generates a plurality of light emission control signals in response to the scan control signal SCS and outputs the plurality of light emission control signals to light emission signal lines EL1 to ELn respectively corresponding thereto.

Although the plurality of scan signals and the plurality of light emission control signals are illustrated as being output from the single scan driving circuit SDC in FIG. 1, the present disclosure is not limited thereto. In one embodiment of the present disclosure, the display device DD may include a plurality of scan driving circuits. In addition, in one embodiment of the present disclosure, a driving circuit for generating and outputting the plurality of scan signals and a driving circuit for generating and outputting the plurality of light emission control signals may be formed separately from each other.

The data driving circuit DDC receives the data control signal DCS and the image data D-RGB from the timing controller TC. The data driving circuit DDC converts the image data D-RGB into data signals, and outputs the data signals to a plurality of data lines DL1 to DLm, which will be described later. The data signals are analog voltages corresponding to grayscale values of the image data D-RGB.

The light emitting display panel DP may include a plurality of groups of scan lines. FIG. 1 shows the scan signal lines SL11 to SL1n of a first group as an example. The light emitting display panel DP includes the light emission signal lines EL1 to ELn, the data lines DL1 to DLm, a first voltage line VL1, a second voltage line VL2, a third voltage line VL3, and a fourth voltage line VL4, and a plurality of pixels PX.

The scan signal lines SL11 to SL1n of the first group may extend in a first direction DR1 and may be aligned in a second direction DR2. The data lines DL1 to DLm may intersect with the scan signal lines SL11 to SL1n of the first group.

The first voltage line VL1 receives a first power voltage ELVSS. The second voltage line VL2 receives a second power voltage ELVDD. The second power voltage ELVDD has a higher level than the first power voltage ELVSS. The third voltage line VL3 receives a reference voltage Vref (hereinafter, referred to as a first voltage). The fourth voltage line VL4 receives an initialization voltage Vint (hereinafter, referred to as a second voltage). The first voltage Vref has a lower level than the second power voltage ELVDD. The second voltage Vint has a lower level than the second power voltage ELVDD. In the present embodiment, the second voltage Vint may have a lower level than the first voltage Vref and the first power voltage ELVSS.

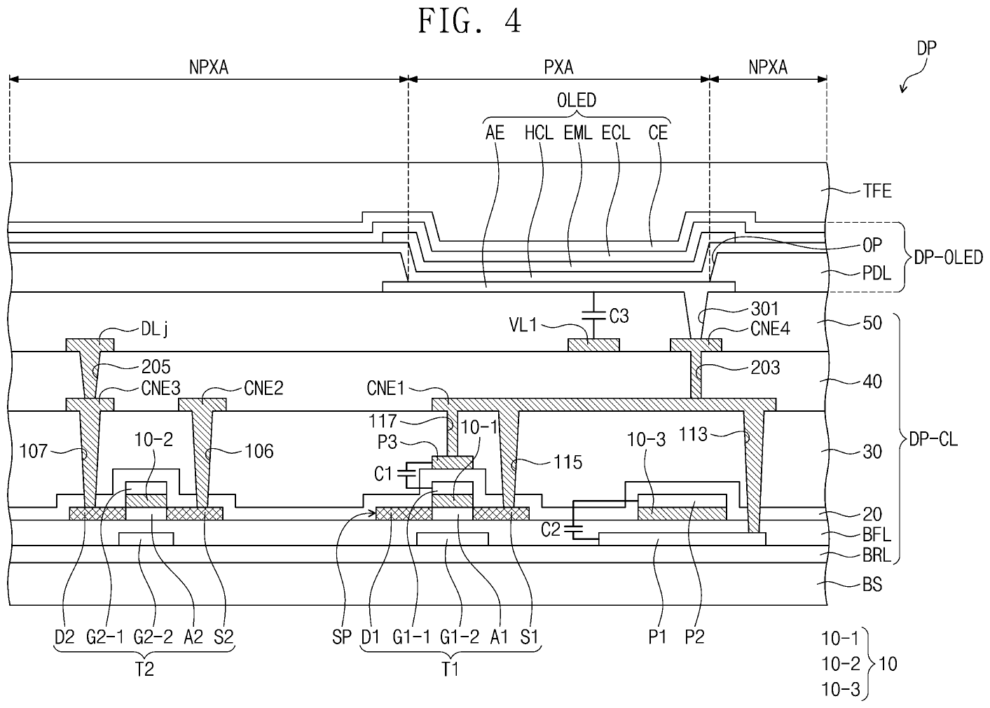

At least one of the first voltage line VL1, the second voltage line VL2, the third voltage line VL3, and the fourth voltage line VL4 may include at least one of a line extending in the first direction DR1 and a line extending in the second direction DR2. The line extending in the first direction DR1 and the line extending in the second direction DR2 of the voltage lines may be electrically connected to each other even though they are disposed on different layers among a plurality of insulating layers 10 to 40 shown in FIG. 4.

Hereinabove, the display device DD according to one embodiment has been described with reference to FIG. 1, but the display device DD of the present disclosure is not limited thereto. Depending on a configuration of a pixel circuit, additional signal lines may be added or omitted. In addition, an electrical connection relationship between the single pixel PX and the signal lines may also be changed.

The plurality of pixels PX may include a plurality of groups generating light of different colors. For example, the plurality of pixels PX may include red pixels generating red color light, green pixels generating green color light, and blue pixels generating blue color light. A light emitting element of the red pixel, a light emitting element of the green pixel, and a light emitting element of the blue pixel may include light emitting layers of different materials.

The pixel circuit may include a plurality of transistors and at least one capacitor. At least one of the scan driving circuit SDC and the data driving circuit DDC may include a plurality of transistors formed via the same process as those of the pixel circuit.

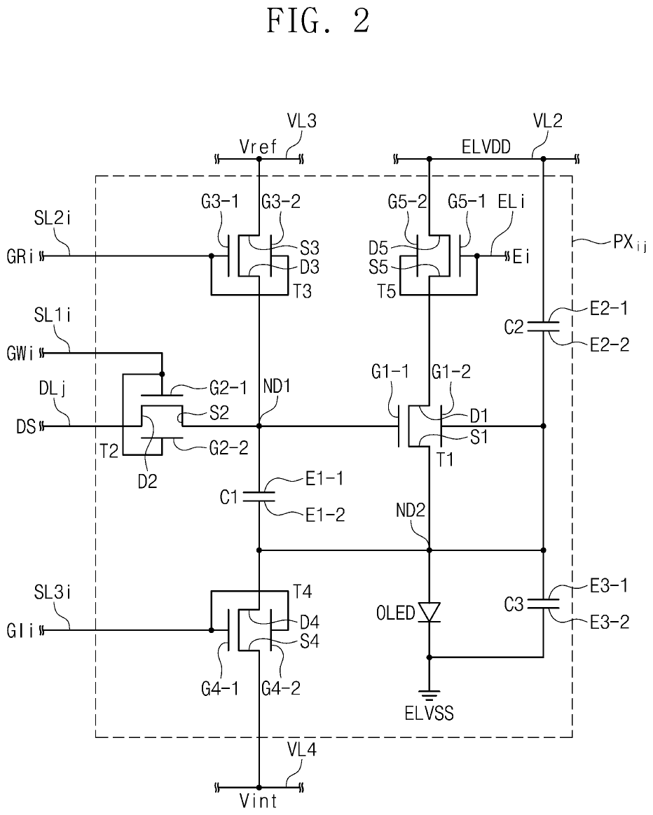

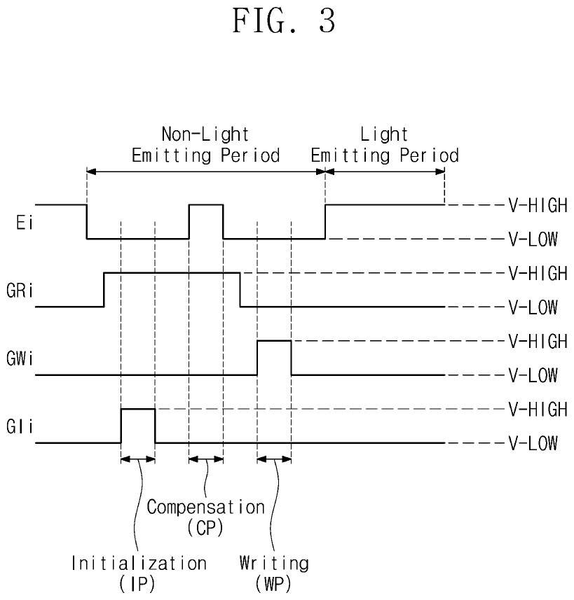

FIG. 2 is an equivalent circuit diagram of a pixel PXij according to an embodiment of the present disclosure. FIG. 3 is a timing diagram of driving signals for driving the pixel PXij shown in FIG. 2.

In FIG. 2, the pixel PXij connected to the i-th scan line SL1i among the scan lines SL11 to SL1n (see FIG. 1) of the first group and to the j-th data line DLj among the plurality of data lines DL1 to DLm (see FIG. 1) is representatively shown. The pixel PXij is connected to an i-th scan line SL2i among scan lines of a second group and is connected to an i-th scan line SL3i among scan lines of a third group.

In the present embodiment, the pixel circuit may include first to fifth transistors T1 to T5, first to third capacitors C1 to C3, and a light emitting element OLED. In the present embodiment, the first to fifth transistors T1 to T5 are described as N-type transistors. However, the present disclosure may not be limited thereto, and at least one of the first to fifth transistors T1 to T5 may be a P-type transistor. In addition, in one embodiment of the present disclosure, at least one of the first to fifth transistors T1 to T5 may be omitted or an additional transistor may be further included in the pixel PXij.

In the present embodiment, each of the first to fifth transistors T1 to T5 is illustrated as including two gates, but at least one transistor may include only one gate. An upper gate G2-1, G3-1, G4-1, or G5-1 and a lower gate G2-2, G3-2, G4-2, or G5-2 of each of the second to fifth transistors T2 to T5 are illustrated as being electrically connected to each other, but the present disclosure is not limited thereto. Each of the lower gates G2-2, G3-2, G4-2, and G5-2 of each of the second to fifth transistors T2 to T5 may be a floating electrode.

In the present embodiment, the first transistor T1 may be a driving transistor, and the second transistor T2 may be a switching transistor. A node to which a gate (hereinafter, referred to as a first upper gate) G1-1 of the first transistor T1 is connected may be defined as a first node ND1, and a node to which a source S1 of the first transistor T1 is connected may be defined as a second node ND2.

The light emitting element OLED includes a first electrode electrically connected to the first node ND2, a second electrode receiving the first power voltage ELVSS, and a light emitting layer disposed between the first electrode and the second electrode. A detailed description of the light emitting element OLED will be made later.

The first transistor T1 is electrically connected between the second voltage line VL2 receiving the second power voltage ELVDD and the second node ND2. The first transistor T1 may include the source (hereinafter, referred to as the first source) S1 connected to the second node ND2, a drain (hereinafter, referred to as a first drain) D1, a channel area (or a semiconductor area), and the first upper gate G1-1. The first transistor T1 may further include a gate (hereinafter, referred to as a first lower gate) G1-2 connected to the second node ND2. The first transistor T1 controls a driving current of the light emitting element OLED based on a charge capacity of the first capacitor C1.

The second transistor T2 is electrically connected between the j-th data line DLj and the first node ND1. The second transistor T2 may include a source (hereinafter, referred to as a second source) S2 connected to the first node ND1, a drain (hereinafter, referred to as a second drain) D2 connected to the j-th data line DLj, a channel area, and the gate (hereinafter, referred to as the second upper gate) G2-1 connected to the i-th scan line SL1i of the first group. The second transistor T2 may further include the gate (hereinafter, referred to as the second lower gate) G2-2 electrically connected to the second upper gate G2-1. The third to fifth transistors T3 to T5 to be described later may include the upper gates G3-1, G4-1, and G5-1 and the lower gates G3-2, G4-2, and G5-2 corresponding to the second upper gate G2-1 and the second lower gate G2-2, respectively. The second transistor T2 provides a data voltage to the first capacitor C1.

The third transistor T3 is electrically connected between the first node ND1 and the third voltage line VL3 receiving the first voltage Vref. The third transistor T3 may include a drain (hereinafter, referred to as a third drain) D3 connected to the first node ND1, a source (hereinafter, referred to as a third source) S3 connected to the third voltage line VL3, a channel area, and the third upper gate G3-1 connected to the i-th scan line SL2i of the second group.

The fourth transistor T4 is electrically connected between the fourth voltage line VL4 receiving the second voltage Vint and the second node ND2. The fourth transistor T4 may include a drain (hereinafter, referred to as a fourth drain) D4 connected to the second node ND2, a source (hereinafter, referred to as a fourth source) S4 connected to the fourth voltage line VL4, a channel area, and the fourth upper gate G4-1 connected to the i-th scan line SL3i of the third group.

The fifth transistor T5 is electrically connected between the second voltage line VL2 and the first drain D1. In the present embodiment, the fifth transistor T5 may include a source (hereinafter, referred to as a fifth source) S5 connected to the second voltage line VL2, a drain (hereinafter, referred to as a fifth drain) D5 connected to the first drain D1, a channel area, and the fifth upper gate G5-1 connected to the i-th light emission signal line ELi.

The first capacitor C1 is electrically connected between the first node ND1 and the second node ND2. The first capacitor C1 includes a first electrode E1-1 connected to the first node ND1 and a second electrode E1-2 connected to the second node ND2.

The second capacitor C2 is electrically connected between the second voltage line VL2 and the second node ND2. The second capacitor C2 includes a first electrode E2-1 connected to the second voltage line VL2 and a second electrode E2-2 connected to the second node ND2.

The third capacitor C3 is electrically connected between the first electrode and the second electrode of the light emitting element OLED. The third capacitor C3 includes a first electrode E3-1 connected to the first electrode of the light emitting element OLED and a second electrode E3-2 connected to the second electrode of the light emitting element OLED.

An operation of the pixel PXij will be described in more detail with reference to FIGS. 2 and 3. The display device DD (see FIG. 1) displays an image for each frame period. The scan lines of the first group, the scan lines of the second group, and the scan lines of the third group, and the light emission signal lines are sequentially scanned during the frame section. FIG. 3 shows a portion of the frame period.

Referring to FIG. 3, each of signals Ei, GRi, GWi, and GIi may have a high level V-HIGH for a partial period and a low level V-LOW for a partial period. Each of the first to fifth transistors T1 to T5 of the N-type described above is turned on when a control signal corresponding thereto has the high level V-HIGH.

A non-light emitting period includes an initialization period IP, a compensation period CP, and a writing period WP.

During the initialization period IP, the third transistor T3 and the fourth transistor T4 are turned on. The first node ND1 is initialized with the first voltage Vref. The second node ND2 is initialized with the second voltage Vint. The first capacitor C1 is initialized with a difference between the first voltage Vref and the second voltage Vint. The second capacitor C2 is initialized with a difference between the second power voltage ELVDD and the second voltage Vint. The third capacitor C3 is initialized with a difference between the first power voltage ELVSS and the second voltage Vint.

During the compensation period CP, the third transistor T3 and the fifth transistor T5 are turned on. In the first capacitor C1, a voltage corresponding to a threshold voltage of the first transistor T1 is compensated.

During the writing period WP, the second transistor T2 is turned on. The second transistor T2 outputs a voltage (or a data voltage) corresponding to a data signal DS. As a result, the first capacitor C1 is charged at a voltage level corresponding to the data signal DS. The data signal DS in which the threshold voltage of the first transistor T1 is compensated is transmitted to the first capacitor C1. Threshold voltages of the driving transistors may be different for each pixel PX (see FIG. 1). The pixel PXij shown in FIGS. 2 and 3 may provide a current with a magnitude proportional to the data signal DS to the light emitting element OLED regardless of a deviation of the threshold voltages of the driving transistors.

Thereafter, during a light emitting period, the fifth transistor T5 is turned on. The first transistor T1 provides a current corresponding to a quantity of charges stored in the first capacitor C1 to the light emitting element OLED. The light emitting element OLED may emit light with a luminance corresponding to the data signal DS.

FIG. 4 is a cross-sectional view of the display panel DP according to an embodiment of the present disclosure. FIG. 4 shows a cross-section of a portion corresponding to some components of the pixel PXij shown in FIG. 2.

Referring to FIG. 4, the display panel DP may include a base layer BS, a circuit element layer DP-CL disposed on the base layer BS, a display element layer DP-OLED, and a thin film encapsulation layer TFE. The base layer BS may be referred to as a base substrate. The display panel DP may further include functional layers such as an anti-reflection layer or a refractive index adjusting layer. The circuit element layer DP-CL includes at least a plurality of insulating layers and circuit elements. The insulating layers to be described below may include an organic layer or an inorganic layer.

The insulating layer, a semiconductor layer, and a conductive layer are formed via processes such as coating and deposition. Thereafter, the insulating layer, the semiconductor layer, and the conductive layer may be selectively patterned via processes of photolithography and etching. Via such process, a semiconductor pattern, a conductive pattern, a signal line, and the like are formed. Patterns disposed on the same layer are formed via the same process.

The base layer BS may include a synthetic resin film. A synthetic resin layer may contain a thermosetting resin. In particular, the synthetic resin layer may be a polyimide-based resin layer, and a material thereof is not particularly limited. The synthetic resin layer may contain at least one of an acrylic resin, a methacrylic resin, a polyisoprene, a vinyl-based resin, an epoxy-based resin, a urethane-based resin, a cellulose-based resin, a siloxane-based resin, a polyamide-based resin, and a perylene-based resin. In addition, the base layer may include a glass substrate, a metal substrate, an organic/inorganic composite material substrate, or the like. The base layer may include a first polyimide layer, a second polyimide layer, and an inorganic layer disposed therebetween.

At least one inorganic layer is formed on a top surface of the base layer BS. The inorganic layer may contain at least one of aluminum oxide, titanium oxide, silicon oxide, silicon nitride, silicon oxynitride, zirconium oxide, and hafnium oxide. The inorganic layer may be formed of multiple layers. The multi-layered inorganic layers may constitute a barrier layer BRL or a buffer layer BFL to be described later. The barrier layer BRL and the buffer layer BFL may be selectively disposed.

The barrier layer BRL prevents foreign substances from entering from the outside. The barrier layer BRL may include a silicon oxide layer and a silicon nitride layer. The silicon oxide layer and the silicon nitride layer may respectively include a plurality of silicon oxide layers and a plurality of silicon nitride layers, and the silicon oxide layers and the silicon nitride layers may be alternately stacked.

A conductive layer (hereinafter, referred to as a first conductive layer) is disposed on the barrier layer BRL. The first conductive layer may include a plurality of conductive patterns. FIG. 4 shows some patterns of the first conductive layer. The first lower gate G1-2, the second lower gate G2-2, and a first conductive pattern P1 are illustrated as examples of the conductive patterns of the first conductive layer.

The first conductive pattern P1 defines the second electrode E2-2 of the second capacitor C2 shown in FIG. 2. In FIG. 4, the first lower gate G1-2 and the first conductive pattern P1 are shown as being spaced apart from each other, but they may be electrically connected to each other. The first lower gate G1-2 and the first conductive pattern P1 may be connected to each other via conductive patterns disposed on different layers, or may have an integral shape on a plane.

The buffer layer BFL may be disposed on the barrier layer BRL so as to cover the first lower gate G1-2, the second lower gate G2-2, and the first conductive pattern P1. The buffer layer BFL improves a bonding force between the base layer BS and the semiconductor pattern and/or the conductive pattern. The buffer layer BFL may include a silicon oxide layer and a silicon nitride layer. The silicon oxide layer and the silicon nitride layer may be alternately stacked.

A semiconductor layer is disposed on the buffer layer BFL. The semiconductor layer may include a plurality of semiconductor patterns. In the present embodiment, the semiconductor pattern may be a metal oxide semiconductor pattern SP. The metal oxide semiconductor pattern SP may include a crystalline or amorphous oxide semiconductor. For example, the metal oxide semiconductor pattern SP may contain metal oxide of zinc (Zn), indium (In), gallium (Ga), tin (Sn), or titanium (Ti), or a mixture of metal such as zinc (Zn), indium (In), gallium (Ga), tin (Sn), and titanium (Ti) and oxide thereof. An oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), and the like. In an embodiment, the metal oxide semiconductor pattern SP may include indium-gallium-zinc-tin oxide (IGZTO).

The metal oxide semiconductor pattern SP may include a plurality of areas classified based on whether the metal oxide is reduced. An area where the metal oxide is reduced (hereinafter, referred to as a reduced area) has higher conductivity than an area where the metal oxide is not reduced (hereinafter, referred to as a non-reduced area). The reduced area substantially serves as a source area, a drain area, or a signal transmitting area of a transistor. The non-reduced area substantially corresponds to a channel area (or a semiconductor area or a non-reduced area) of the transistor. In other words, a portion of the semiconductor pattern may be the channel area of the transistor, another portion thereof may be the source area or the drain area of the transistor, and another portion thereof may be the signal transmitting area.

The source area or the drain area may itself be the source or the drain of each of the transistors T1 to T5 described in FIG. 2. The source or the drain of each of the transistors T1 to T5 may include the source area or the drain area of the semiconductor pattern described above and the conductive pattern connected thereto. Hereinafter, for convenience of description, the source area or the drain area of the metal oxide semiconductor pattern SP is referred to as the source or the drain.

As shown in FIG. 4, the first transistor T1 includes the metal oxide semiconductor pattern SP including the source S1, a channel area A1, and the drain D1. The source S1 and the drain D1 of the first transistor T1 extend in opposite directions from the channel area A1. The source S2, a channel area A2, and the drain D2 of the second transistor T2 are also formed from the semiconductor pattern.

The first lower gate G1-2 and the second lower gate G2-2 described above have a function of a light blocking pattern. The first lower gate G1-2 and the second lower gate G2-2 are disposed below the channel area A1 of the first transistor T1 and the channel area A2 of the second transistor T2, respectively, to block light incident thereon from the outside. The first lower gate G1-2 and the second lower gate G2-2 prevent external light from changing voltage-current characteristics of the first transistor T1 and the second transistor T2, respectively.

A first insulating layer 10 is disposed on the buffer layer BFL. In the present embodiment, the first insulating layer 10 is not formed across an entirety of the display panel DP, but overlaps only the channel area of the transistor or a specific conductive pattern to be described later. The first insulating layer 10 includes a plurality of insulating patterns. FIG. 4 illustrates a first insulating pattern 10-1, a second insulating pattern 10-2, and a third insulating pattern 10-3 as an example. In one embodiment of the present disclosure, the first insulating layer 10 may not be patterned. In this regard, the first insulating layer 10 may cover the metal oxide semiconductor pattern SP.

The first insulating pattern 10-1 and the second insulating pattern 10-2 respectively overlap the first upper gate G1-1 and the second upper gate G2-1 to be described later. The third insulating pattern 10-3 overlaps a second conductive pattern P2 to be described later.

A conductive layer (hereinafter, referred to as a second conductive layer) is disposed on the first insulating layer 10. The second conductive layer may include a plurality of conductive patterns respectively overlapping the patterns of the first insulating layer 10. In FIG. 4, the first upper gate G1-1, the second upper gate G2-1, and the second conductive pattern P2 are shown as examples of the conductive patterns of the second conductive layer. Because the second conductive layer and the first insulating layer 10 are etched via the same process, the conductive pattern of the second conductive layer and the insulating pattern of the first insulating layer 10 may have substantially the same shape. An edge of the conductive pattern of the second conductive layer and an edge of the insulating pattern of the first insulating layer 10 overlapping each other are aligned. The first upper gate G1-1 may define the first electrode E1-1 of the first capacitor C1 shown in FIG. 2. The first upper gate G1-1 may extend from the first electrode E1-1 of the first capacitor C1 on a plane, and accordingly, the first upper gate G1-1 may be defined as a portion of the first electrode E1-1 of the first capacitor C1.

The second conductive pattern P2 defines the first electrode E2-1 of the second capacitor C2 shown in FIG. 2. Although not shown, the second conductive pattern P2 may be electrically connected to the second voltage line VL2.

A second insulating layer 20 covering the first upper gate G1-1, the second upper gate G2-1, and the second conductive pattern P2 is disposed on the buffer layer BFL. The second insulating layer 20 may be an inorganic layer or an organic layer, and may have a single-layer or multi-layer structure (e.g. including an inorganic layer and an organic layer). The second insulating layer 20 may cover the source S1 and the drain D1 of the first transistor T1 and the source S2 and the drain D2 of the second transistor T2. The second insulating layer 20 may cover side surfaces of each of the first insulating pattern 10-1, the second insulating pattern 10-2, and the third insulating pattern 10-3.

A conductive layer (hereinafter, referred to as a third conductive layer) is disposed on the second insulating layer 20. The third conductive layer may include a plurality of conductive patterns respectively overlapping the second insulating layer 20. The third conductive layer may include a third conductive pattern P3 overlapping the first upper gate G1-1. The third conductive pattern P3 defines the second electrode E1-2 of the first capacitor C1 shown in FIG. 2. The third conductive pattern P3 may extend from the second electrode E1-2 of the first capacitor C1 on a plane, and accordingly, the third conductive pattern P3 may be defined as a portion of the second electrode E1-2 of the first capacitor C1.

In one embodiment of the present disclosure, even when the third conductive layer includes the conductive pattern, the third conductive pattern P3 overlapping the first upper gate G1-1 may be omitted. That is, the second electrode E1-2 of the first capacitor C1 may not overlap the first upper gate G1-1.

A third insulating layer 30 covering the third conductive pattern P3 is disposed on the second insulating layer 20. In the present embodiment, the third insulating layer 30 may be an inorganic layer or an organic layer, and may have a single-layer or multi-layer structure (e.g. including an inorganic layer and an organic layer).

A conductive layer (hereinafter, referred to as a fourth conductive layer) is disposed on the third insulating layer 30. The fourth conductive layer may include a plurality of conductive patterns. The fourth conductive layer may include a plurality of connection electrodes. FIG. 4 illustrates first to third connection electrodes CNE1 to CNE3 as an example. The first connection electrode CNE1 may be connected to the first conductive pattern P1 via a contact hole 113 extending through the buffer layer BFL and the second and third insulating layers 20 and 30, connected to the first source S1 via a contact hole 115 extending through the second and third insulating layers 20 and 30, and may be connected to the third conductive pattern P3 via a contact hole 117 extending through the third insulating layer 30. The second connection electrode CNE2 is connected to the second source S2 via a contact hole 106 extending through the second and third insulating layers 20 and 30, and the third connection electrode CNE3 is connected to the second drain D2 via a contact hole 107 extending through the second and third insulating layers 20 and 30.

A fourth insulating layer 40 covering the fourth conductive layer is disposed on the third insulating layer 30. In the present embodiment, the fourth insulating layer 40 may be an organic layer and may have a single-layer structure, but may not be particularly limited.

A conductive layer (hereinafter, referred to as a fifth conductive layer) is disposed on the fourth insulating layer 40. The fifth conductive layer may include a plurality of conductive patterns. The fifth conductive layer includes a fourth connection electrode CNE4. The fourth connection electrode CNE4 is connected to the first connection electrode CNE1 via a contact hole 203 extending through the fourth insulating layer 40.

The fifth conductive layer may further include the data line DLj and the first voltage line VL1. The data line DLj may be connected to the third connection electrode CNE3 via a contact hole 205 extending through the fourth insulating layer 40. A portion of the first voltage line VL1 overlapping a first electrode AE of the light emitting element OLED to be described later defines the second electrode E3-2 of the third capacitor C3 shown in FIG. 2. A portion of the first electrode AE of the light emitting element OLED defines the first electrode E3-1 of the third capacitor C3 shown in FIG. 2.

A fifth insulating layer 50 covering the fourth conductive layer is disposed on the fourth insulating layer 40. In the present embodiment, the fifth insulating layer 50 may be an organic layer and may have a single-layer structure, but may not be particularly limited.

The first electrode AE of the light emitting element OLED is disposed on the fifth insulating layer 50. The first electrode AE may be an anode. A pixel defining layer PDL is disposed on the fifth insulating layer 50. The first electrode AE is connected to a forth connection electrode CNE4 via a contact hole 301 extending through the fifth insulating layer 50.

An opening OP of the pixel defining layer PDL exposes at least a portion of the first electrode AE. The opening OP of the pixel defining layer PDL may define a light emitting area PXA. For example, the plurality of pixels PX (see FIG. 1) may be arranged in a regular manner on a plane of the display panel DP (see FIG. 1). An area where the plurality of pixels PX are disposed may be defined as a pixel area, and one pixel area may include the light emitting area PXA and a non-light emitting area NPXA adjacent to the light emitting area PXA. The non-light emitting area NPXA may surround the light emitting area PXA.

A hole control layer HCL may be disposed in the light emitting area PXA and the non-light emitting area NPXA in a common manner. A common layer such as the hole control layer HCL may be formed in the plurality of pixels PX in a common manner. The hole control layer HCL may include a hole transport layer and a hole injection layer.

A light emitting layer EML is disposed on the hole control layer HCL. The light emitting layer EML may be disposed only in an area corresponding to the opening OP. The light emitting layer EML may be formed separately in each of the plurality of pixels PX.

Although the patterned light emitting layer EML is illustrated as an example in the present embodiment, the light emitting layer EML may be disposed in the plurality of pixels PX in a common manner. The light emitting layer EML disposed in a common manner may generate white light or blue light. In addition, the light emitting layer EML may have a multi-layer structure.

An electron control layer ECL is disposed on the light emitting layer EML. The electron control layer ECL may include an electron transport layer and an electron injection layer. A second electrode CE is disposed on the electron control layer ECL. The second electrode CE may be a cathode. The electron control layer ECL and the second electrode CE are disposed in the plurality of pixels PX in a common manner.

The thin film encapsulation layer TFE is disposed on the second electrode CE. The thin film encapsulation layer TFE is disposed in the plurality of pixels PX in a common manner. In the present embodiment, the thin film encapsulation layer TFE directly covers the second electrode CE. In one embodiment of the present disclosure, a capping layer directly covering the second electrode CE may be further disposed. In one embodiment of the present disclosure, a stacked structure of the light emitting element OLED may be inverted vertically from the structure shown in FIG. 4.

The thin film encapsulation layer TFE includes at least an inorganic layer or an organic layer. In one embodiment of the present disclosure, the thin film encapsulation layer TFE may include two inorganic layers and an organic layer disposed therebetween. In one embodiment of the present disclosure, the thin film encapsulation layer may include a plurality of inorganic layers and a plurality of organic layers that are alternately stacked.

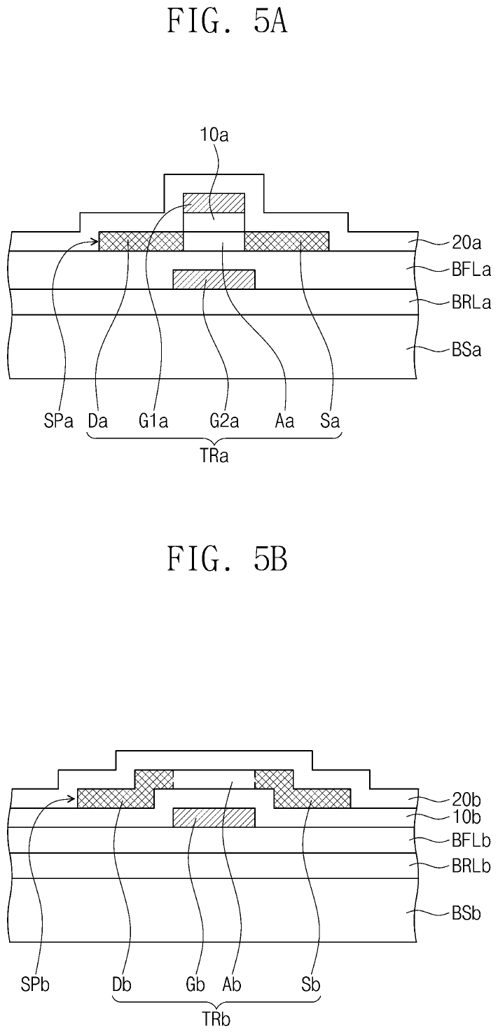

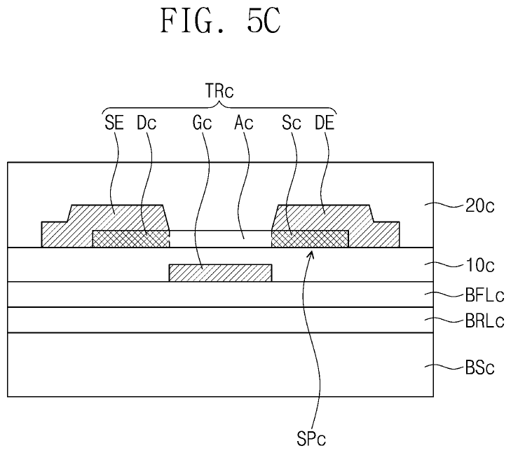

FIGS. 5A to 5C are cross-sectional views of a transistor according to an embodiment of the present disclosure. The transistors shown in FIGS. 5A to 5C are examples of at least one of the first to fifth transistors T1, T2, T3, T4, and T5 shown in FIG. 2. Hereinafter, the present disclosure will be described with reference to FIGS. 5A to 5C.

As shown in FIG. 5A, a transistor TRa may include an upper gate electrode G1a, a lower gate electrode G2a, and a semiconductor pattern SPa. The semiconductor pattern Spa may include a source Sa, a channel area Aa, and a drain Da. The transistor TRa may have a structure substantially corresponding to that of the second transistor T2 shown in FIG. 4. Accordingly, a base layer BSa, a barrier layer BRLa, a buffer layer BFLa, a first insulating layer 10a, and a second insulating layer 20a may respectively correspond to the insulating layers BS, BRL, BFL, 10, and 20. In the present embodiment, the lower gate electrode G2a may be disposed between the barrier layer BRLa and he buffer layer BFLa. In an embodiment, the upper gate electrode G1a may be disposed on the semiconductor pattern SPa. An insulating layer in contact with the channel area Aa may be the first insulating layer 10a, and may be disposed between the upper gate electrode G1a and the semiconductor pattern SPa. In the present embodiment, the first insulating layer 10a may be patterned to correspond to the gate electrode Ga.

Alternatively, as shown in FIG. 5B, in a transistor TRb, a semiconductor pattern SPb may be disposed on a gate electrode Gb. The semiconductor pattern SPb may include a source Sb, a channel area Ab, and a drain Db. An insulating layer in contact with the channel area Ab may be a second insulating layer 20b. In the present embodiment, the second insulating layer 20b may be entirely in contact with and cover the semiconductor pattern SPb. Although not shown, an additional connection electrode or the like may be further included, and the connection electrode may extend through the second insulating layer 20b and be connected to the source Sb or the drain Db. The transistor TRb may include a base layer BSb, a barrier layer BRLb, and a buffer layer BFLb.

Alternatively, as shown in FIG. 5C, in a transistor TRc, a semiconductor pattern SPc may be disposed on a gate electrode Gc. The semiconductor pattern SPc may include a source Sc, a channel area Ac, and a drain Dc. An insulating layer in contact with the channel area Ac may be a second insulating layer 20c. The transistor TRc may include a base layer BSc, a barrier layer BRLc, and a buffer layer BFLc.

In this regard, a source electrode SE and a drain electrode DE may be further formed separately. The source electrode SE and the drain electrode DE are illustrated as covering the semiconductor pattern SPc and formed on a first insulating layer 10c. Accordingly, an entirety of the second insulating layer 20c may be in contact with and cover the channel area Ac of the semiconductor pattern SPc, the source electrode SE, and the drain electrode DE.

The transistors TRa, TRb, and TRc according to an embodiment of the present disclosure may include the insulating layers 10a, 20b, and 20c in contact with the semiconductor patterns SPa, SPb, and SPc, especially, the channel areas Aa, Ab, and Ac, respectively. According to the present disclosure, the transistors TRa, TRb, and TRc with improved mobility via hydrogen inflow from the insulating layers 10a, 20b, and 20c that form interfaces with the channel areas Aa, Ab, and Ac, respectively, may be formed. The transistor according to the present disclosure may be formed in various structures and may not be limited to any one embodiment.

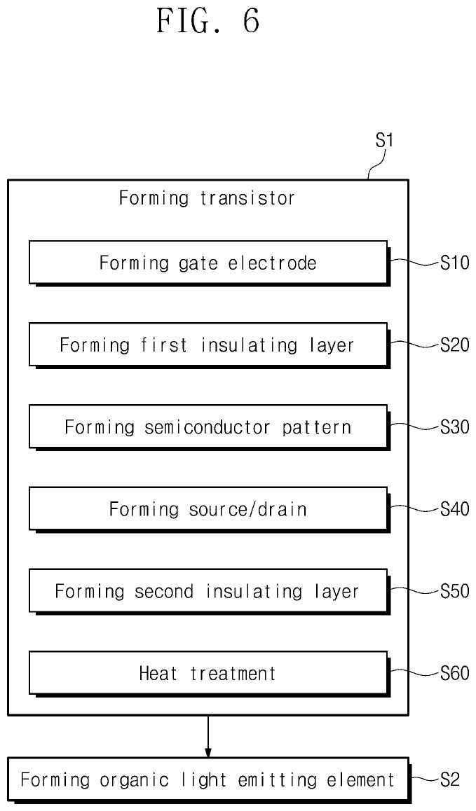

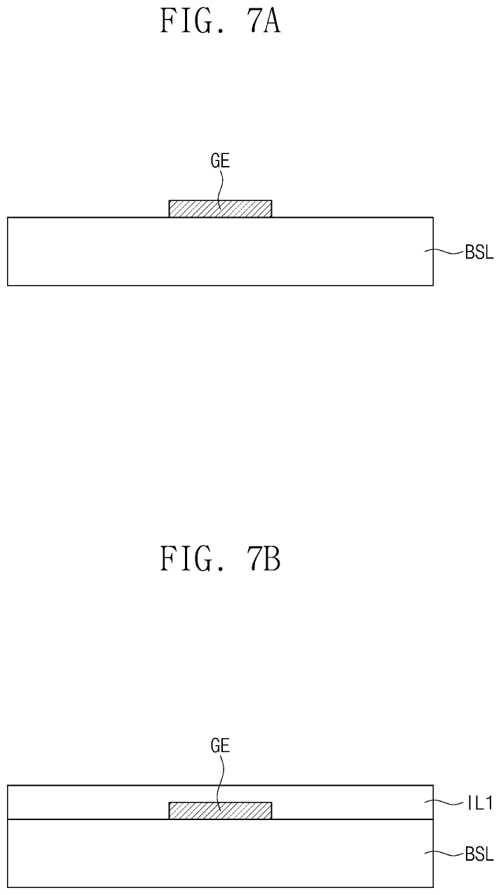

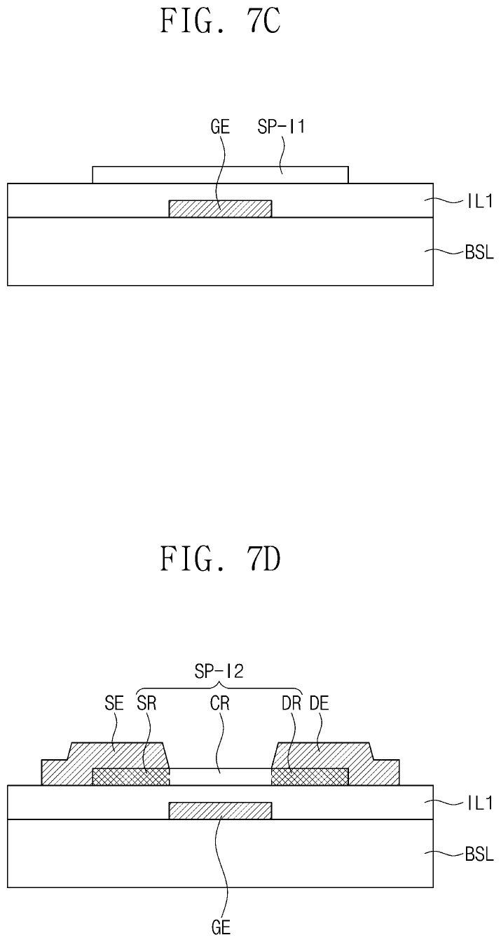

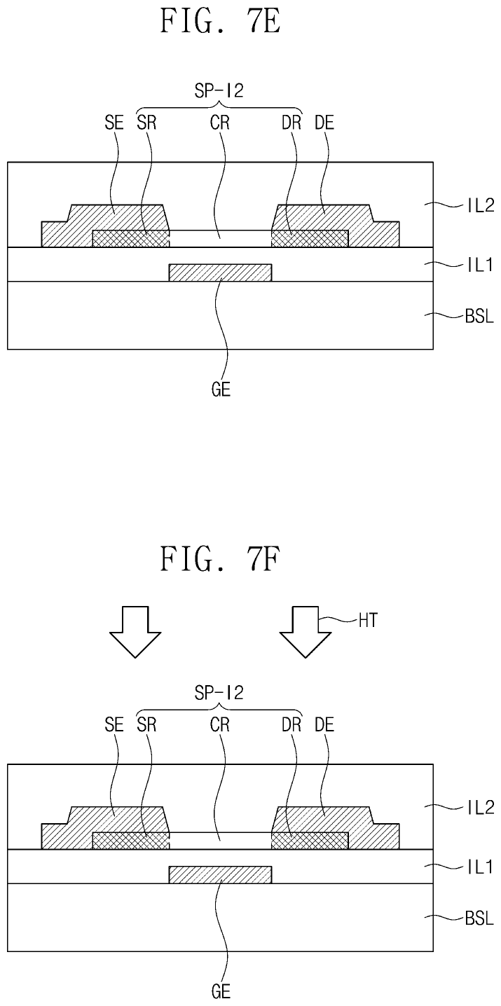

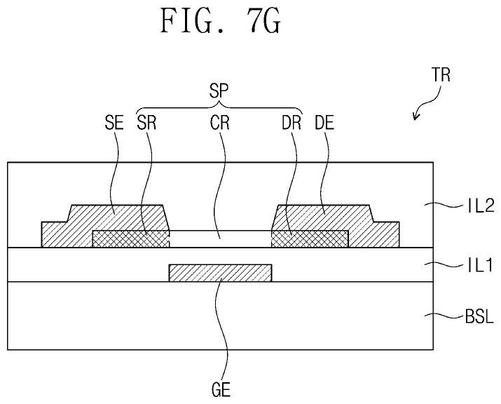

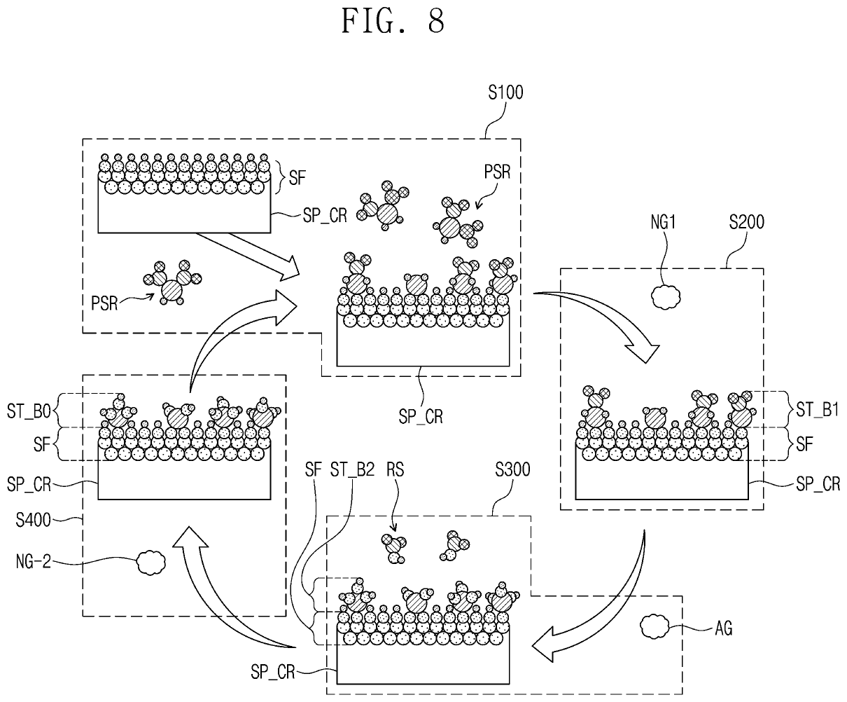

FIG. 6 is a block diagram illustrating a method of manufacturing a display panel according to an embodiment of the present disclosure. FIGS. 7A to 7G are cross-sectional views illustrating a method of manufacturing a display panel according to an embodiment of the present disclosure. FIG. 8 is a cross-sectional view illustrating a method of manufacturing a display panel according to an embodiment of the present disclosure. Hereinafter, the present disclosure will be described with reference to FIGS. 6 to 8.

As shown in FIG. 6, a method of manufacturing a display panel includes forming a transistor (S1) and forming an organic light emitting element on the transistor (S2). The forming of the transistor (S1) includes forming a gate electrode (S10), forming a first insulating layer (S20), forming a semiconductor pattern (S30), forming a source/drain (S40), forming a second insulating layer (S50), and performing a heat treatment (S60). FIGS. 7A to 7G sequentially show the forming of the transistor (S1).

Referring to FIG. 7A, a gate electrode GE may be formed on a base layer BSL. The gate electrode GE may be formed by patterning a metal. The gate electrode GE may be formed via deposition or sputtering. The base layer BSL may be a layer including at least one of the base substrate BS (see FIG. 4), the barrier layer BRL (see FIG. 4), and the buffer layer BFL (see FIG. 4) described above.

Referring to FIG. 7B, thereafter, a first insulating layer IL1 is formed on the base layer BSL. The first insulating layer IL1 may cover an entirety of the gate electrode GE. The first insulating layer IL1 may be formed by depositing or coating an insulating material on the base layer BSL. The deposition may be physical vapor deposition or chemical vapor deposition.

Referring to FIG. 7C, thereafter, a first initial semiconductor pattern SP-I1 is formed on the first insulating layer IL1. The first initial semiconductor pattern SP-I1 may contain an oxide semiconductor material, for example, a metal oxide semiconductor material. For example, the first initial semiconductor pattern SP-I1 may be formed by patterning an oxide semiconductor layer made of indium gallium zinc tin oxide (IGZTO).

The oxide semiconductor layer containing the indium gallium zinc tin oxide may be formed via a co-sputtering scheme in which indium gallium zinc oxide (IGZO) and tin oxide (SnO₂) are sputtered together. In this regard, an RF voltage may be applied to a chamber. In one example, a composition ratio of indium:gallium:zinc in the indium gallium zinc oxide may be 1:1:1 (at. %), but may not be limited thereto.

After forming the oxide semiconductor layer covering the first insulating layer IL1 via the process such as the sputtering, the oxide semiconductor layer may be patterned via a process such as photolithography to form the first initial semiconductor pattern SP-I1. In this regard, a composition ratio of indium:gallium:zinc:tin in the first initial semiconductor pattern SP-I1 may be 29.4:39.8:12.6:18.2 (at. %), but may not be limited thereto.

Referring to FIG. 7D, thereafter, the source SE and the drain DE may be formed. In the present embodiment, each of the source SE and the drain DE may be formed of conductive patterns. Specifically, after depositing a conductive material on the first insulating layer IL1 to form a conductive layer, the conductive layer may be patterned to form the source SE and the drain DE.

The patterning process of the conductive layer may be performed by an etching gas including plasma. The etching gas may include plasma containing oxygen. In the semiconductor pattern SP, a channel area CR not covered by the source SE and the drain DE may be exposed to the etching gas, and thus, a decrease in a hydrogen concentration may occur. Accordingly, the first initial semiconductor pattern SP-I1 may be formed as a second initial semiconductor pattern SP-I2 including a source area SR, a drain area DR, and the channel area CR.

Thereafter, referring to FIG. 7E, a second insulating layer IL2 may be formed. The second insulating layer IL2 may be formed on the first insulating layer IL1 and may cover all of the second initial semiconductor pattern SP-I2, the source SE, and the drain DE. In particular, the second insulating layer IL2 may cover channel area CR exposed from the source SE and the drain DE in the semiconductor pattern SP. The second insulating layer IL2 may contain silicon oxide. The second insulating layer IL2 may be formed via a plasma enhanced atomic layer deposition (PEALD) method.

Hereinafter, the forming of the initial second insulating layer IL2 will be described in detail with reference to FIG. 8. As shown in FIG. 8, the forming of the second insulating layer IL2 may include four sequential steps (hereinafter, first to fourth steps) (S100, S200, S300, and S400). In FIG. 8, a description is made based on the channel area CR.

The first step (S100) may be a step of introducing a precursor PSR to a surface SF of a channel area SP_CR of the second initial semiconductor pattern SP-I2. The precursor PSR may contain a silicon compound, and specifically may contain di-isopropyl amino silane (DIPAS) represented by Chemical Formula 1.

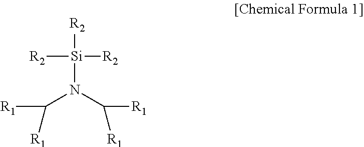

The precursor PSR may chemically bond with the surface SF of the second initial semiconductor pattern SP-I2, that is, a functional group of the semiconductor pattern SP. In this regard, primary structures ST_B1 may be formed on the surface SF of the second initial semiconductor pattern SP-I2 by chemically bonding with the second initial semiconductor pattern SP-I2. The primary structures ST_B1 may contain silicon atoms or a silicon compound.

Thereafter, the second step (S200) may be a step of purging an interior of a chamber with first inert gas NG1. The first inert gas NG1 may include at least one of argon (Ar), krypton (Kr), nitrogen (N₂), and hydrogen (H₂), but may not be limited thereto.

Thereafter, the third step (S300) may be a step of providing reaction gas AG onto the second initial semiconductor pattern SP-I2. In this regard, the silicon atoms or the silicon compound existing on the surface SF of the second initial semiconductor pattern SP-I2 may react with the reaction gas AG to form a secondary structure ST_B2. The secondary structure ST_B2 may contain silicon oxide. The reactive gas AG may include water (H₂O), oxygen (O₂), ozone (O₃), hydrogen peroxide (H₂O₂), oxygen plasma (O₂), or nitric acid plasma (NH₃). In the present embodiment, oxygen plasma is described as the reactive gas AG as an example.

Thereafter, the fourth step (S400) may be a step of purging the interior of the chamber with second inert gas NG2. The second inert gas NG2 may include at least one of argon (Ar), krypton (Kr), nitrogen (N₂), and hydrogen (H₂), but may not be limited thereto. The second inert gas NG2 may be the same as or different from the first inert gas NG1. A residue RS floating in the chamber may be removed via the second inert gas NG2. A structure ST_B0 formed on the surface SF of the channel area SP_CR may contain silicon oxide and a portion of the precursor PSR.

Thereafter, the first step (S100) may proceed again. According to the present disclosure, the initial second insulating layer IL2 having a predetermined thickness may be formed by repeatedly performing the first to fourth steps S100, S200, S300, and S400.

The initial second insulating layer IL2 according to the present disclosure may include the residue of the precursor PSR. The residue of the precursor PSR may be the portion of the precursor PSR. That is, the residue of the precursor PSR may include a portion other than silicon among portions of di-isopropyl amino silane, for example, a Si—N structure, an N-R1 structure, or an R1 structure in Chemical Formula 1.

Thereafter, as shown in FIG. 7F, the second initial semiconductor pattern SP-I2 may become the semiconductor pattern SP via heat treatment (annealing). Hydrogen atoms present in a second insulating layer IL2 may be diffused into the channel area CR of the second initial semiconductor pattern SP-I2 via the heat treatment. Accordingly, the semiconductor pattern SP formed via the heat treatment step may have improved electrical characteristics than the second initial semiconductor pattern SP-I2. Specifically, the semiconductor pattern SP may have higher horizontal mobility (μ_{Lin}) and higher saturation mobility (μ_{Sat}) than the second initial semiconductor pattern SP-I2. In addition, the semiconductor pattern SP may have a subthreshold swing (SS) value higher than that of the second initial semiconductor pattern SP-I2. In addition, the semiconductor pattern SP may have a lower threshold voltage (VTH) value than the second initial semiconductor pattern SP-I2.

In the present embodiment, a heat treatment temperature may be higher than 300° C. and lower than 500° C. Specifically, the heat treatment temperature may be about 400° C. A detailed description thereof will be made later.

According to the present disclosure, the semiconductor pattern SP having the improved electrical characteristics may be formed by forming the second insulating layer IL2 via a plasma enhanced atomic layer deposition process using DIPAS as the precursor. The semiconductor pattern SP may have the high mobility, so that a high-resolution display panel may be easily implemented.

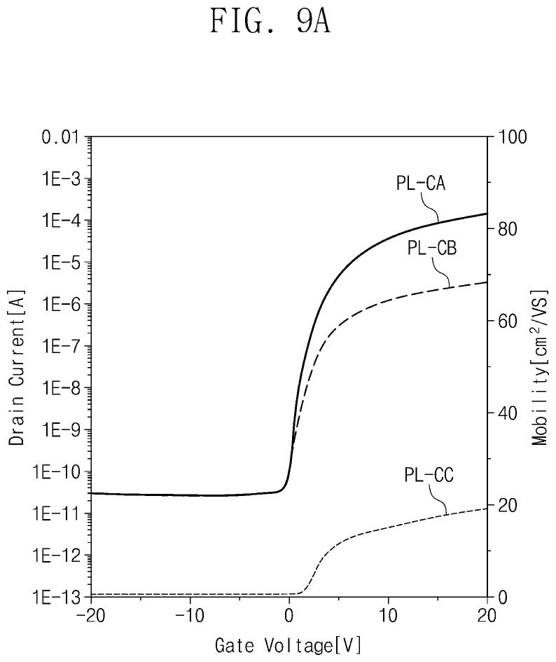

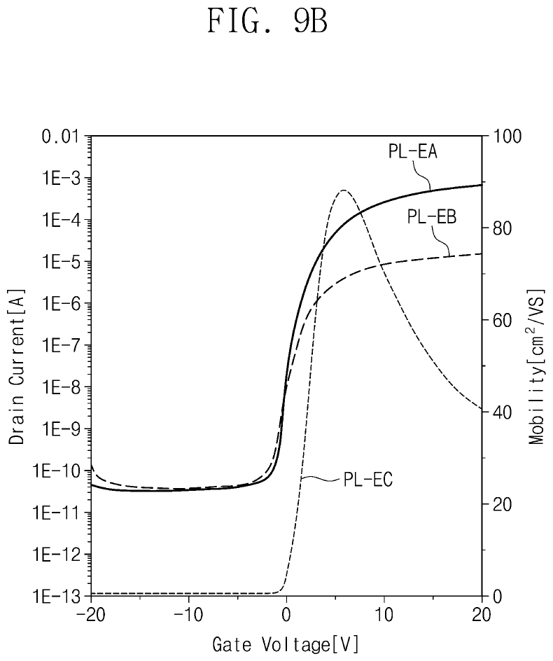

FIGS. 9A and 9B are graphs showing electrical characteristics of Present Example of the present disclosure and Comparative Examples. Each of FIGS. 9A and 9B shows a gate voltage-drain current graph. Hereinafter, the present disclosure will be described with reference to Table 1 and FIGS. 9A and 9B.

TABLE 1

| | | | | | Interfacial |
|---|---|---|---|---|---|
| | Horizontal | Saturation | Subthreshold | Threshold | trap density |
| | mobility | mobility | swing (SS, | voltage | (Dit, |
| Division | (μ_{Lin}, cm²/Vs) | (μ_{Sat}, cm²/Vs) | V/decade) | (V_{TH}, V) | #/cm²eV) |
| Comparative | 21.15 | 9.98 | 0.144 | 0.214 | 2.96E+11 |
| Example 1 | | | | | |
| Comparative | 20.11 | 10.21 | 0.414 | 1.423 | 1.35E+12 |
| Example 2 | | | | | |
| Comparative | 23.26 | 8.39 | 0.363 | −3.297 | 1.14E+12 |
| Example 3 | | | | | |
| Present | 87.73 | 68.56 | 0.244 | 0.030 | 6.94E+11 |
| Example 1 | | | | | |

Table 1 compares electrical characteristics of the semiconductor patterns SP based on a composition with each other. Comparative Example 1 may be a semiconductor pattern containing unpassivated indium gallium zinc oxide, and Comparative Example 2 may be a semiconductor pattern passivated with a silicon oxide layer. Comparative Example 3 may be a semiconductor pattern containing unpassivated indium gallium zinc tin oxide, and Present Example 1 may be a semiconductor pattern containing indium gallium zinc tin oxide passivated with a silicon oxide layer. FIG. 9A shows a gate voltage-drain current graph of Comparative Example 2, and FIG. 9B shows a gate voltage-drain current graph of Present Example. FIGS. 9A and 9B show plots PL-CA and PL-EA when a drain-source voltage is 5.1V, plots PL-CB and PL-EB when the drain-source voltage is 0.1V, and horizontal mobility PL-CC and PL-EC, respectively.

When comparing Comparative Example 1 and Comparative Example 2 in Table 1 with each other, it appears that the horizontal mobility is somewhat reduced and the saturation mobility is somewhat increased in Comparative Example 2 compared to Comparative Example 1. However, it appears that the subthreshold swing value and the threshold voltage value are greatly increased in Comparative Example 2 compared to Comparative Example 1. That is, as the indium gallium zinc oxide semiconductor pattern is covered (or passivated) by the silicon oxide layer, the mobility is somewhat increased, but the threshold voltage is also increased.

When comparing Comparative Example 3 in Table 1 with Present Example, it appears that the horizontal mobility and the saturation mobility are significantly improved in Present Example compared to Comparative Example 3. In addition, although there is a tendency that the subthreshold swing value is somewhat reduced in Present Example 1 compared to Comparative Example 3, but Present Example 1 has the threshold voltage of 0.030 V, which is closer to 0 V than that of Comparative Example 1 or Comparative Example 2. That is, it appears that Present Example 1 has relatively excellent electrical characteristics compared to Comparative Examples 1 to 3.

The semiconductor pattern according to the present disclosure may have the horizontal mobility and the saturation mobility equal to or greater than about 30 cm²/Vs. Present Example was measured to have the horizontal mobility of 87.73 cm²/Vs and the saturation mobility of 68.56 cm²/Vs. That is, it may be seen that the semiconductor pattern according to the present disclosure has a relatively high mobility compared to Comparative Examples, and thus, has the improved electrical characteristics.

On the other hand, it appears that the defect density (Dit) is reduced in the first embodiment compared to Comparative Example 3. That is, according to the present disclosure, by forming the insulating layer IL2 on the indium gallium zinc tin oxide semiconductor pattern, defects present in the indium gallium zinc tin oxide semiconductor pattern, particularly, in the channel area in contact with the insulating layer IL2 may be reduced. Accordingly, the electrical characteristics of the indium gallium zinc tin oxide semiconductor pattern may be improved.

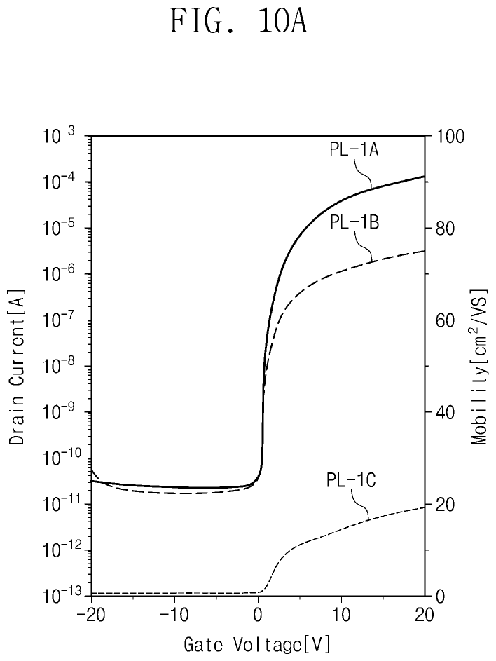

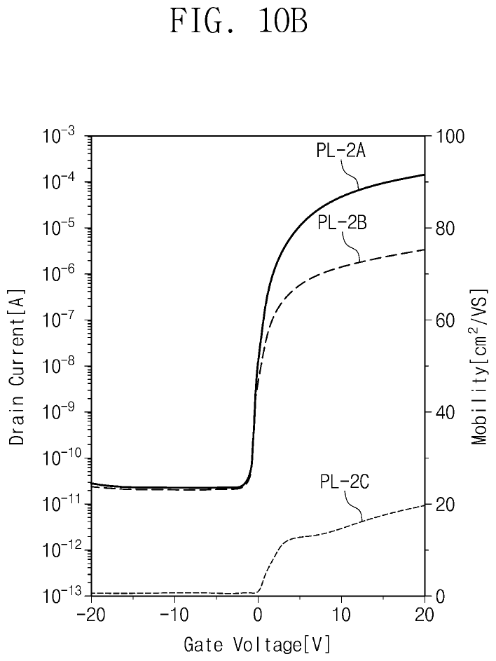

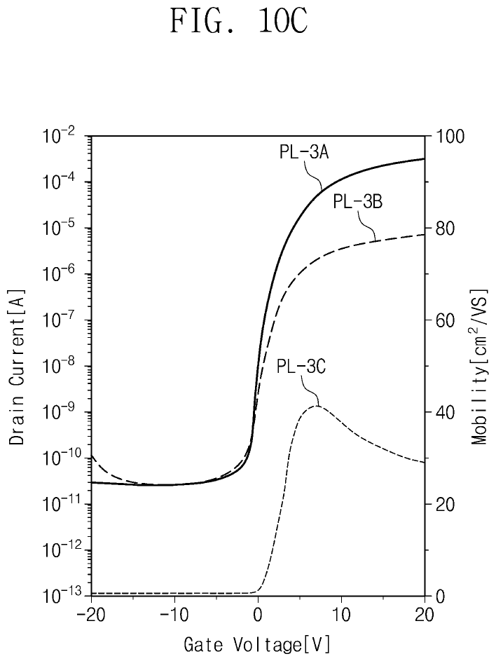

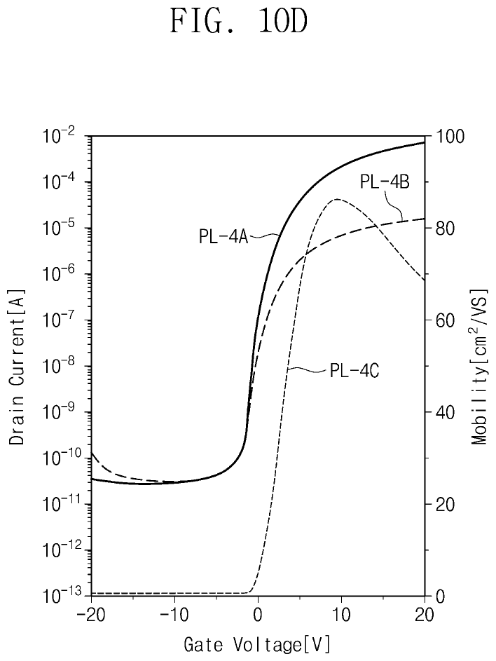

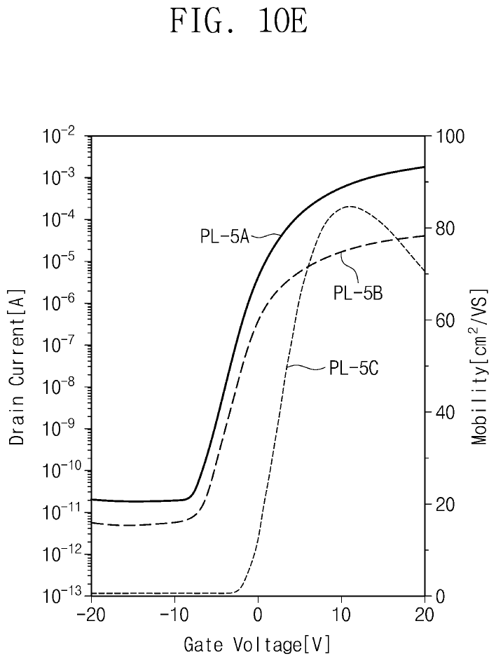

FIGS. 10A to 10E are graphs showing electrical characteristics of Present Example of the present disclosure and Comparative Examples. Each of FIGS. 10A to 10E shows a gate voltage-drain current graph. Hereinafter, the present disclosure will be described with reference to Table 2 below and FIGS. 10A to 10E.

TABLE 2

| | Mobility | Subthreshold | Threshold | Interfacial | Total trap | Composition |
|---|---|---|---|---|---|---|
| | (μ_{FE}, | swing (SS, | voltage | trap density | density | ratio |
| Division | cm2/Vs) | V/decade) | (V_{TH}, V) | (Dit, /cm³eV) | (N_{T.max}, /cm³eV) | (In:Ga:Zn:Sn) |
| Experimental | 19.1 ± 0.19 | 0.18 ± 0.04 | 1.02 ± 0.27 | 4.4 × 10¹¹ | 1.5 × 10¹⁷ | 36:47:17:0 |
| Example 1 | | | | | | |
| Experimental | 19.5 ± 0.12 | 0.27 ± 0.19 | 0.17 ± 0.25 | 7.6 × 10¹¹ | 2.5 × 10¹⁷ | 29:41:14:16 |
| Example 2 | | | | | | |
| Experimental | 41.2 ± 7.99 | 0.31 ± 0.07 | 0.28 ± 0.26 | 9.1 × 10¹¹ | 3.0 × 10¹⁷ | 29:40:13:18 |
| Example 3 | | | | | | |
| Experimental | 85.9 ± 12.1 | 0.33 ± 0.12 | −0.49 ± 0.29 | 9.6 × 10¹¹ | 3.1 × 10¹⁷ | 29:35:11:25 |
| Example 4 | | | | | | |
| Experimental | 212.1 ± 28.9 | 1.60 ± 0.35 | −3.51 ± 1.47 | 5.5 × 10¹² | 1.8 × 10¹⁸ | 27:32:10:31 |
| Example 5 | | | | | | |

Table 2 compares electrical characteristics of the semiconductor patterns SP based on a content of tin (Sn) of the semiconductor patterns SP with each other. Experimental Examples 1 to 5 may be experimental examples obtained by differently adjusting power of tin oxide during sputtering of indium gallium zinc oxide and tin oxide.

Referring to Table 2, it may be seen that a tin composition ratio in the semiconductor pattern containing the indium gallium tin zinc oxide varies by varying the power of the tin oxide. Specifically, in Experimental Examples 1 to 5, the sputtering process may be performed by setting the power of the tin oxide to 0 W, 5 W, 8 W, 10 W, and 12 W, respectively. Experimental Examples 1 to 5 are formed with power increasing in order. Accordingly, it is shown that the tin content ratios of Experimental Examples 1 to 5 increase in order. That is, the tin content in the semiconductor pattern containing the indium gallium tin zinc oxide may be adjusted by adjusting the power of the tin oxide during the sputtering process.

FIGS. 10A to 10E respectively show gate voltage-drain current graphs of Experimental Examples 1 to 5. FIG. 10A shows a plot PL-1A when a drain-source voltage is 5.1 V, a plot PL-1B when the drain-source voltage is 0.1 V, and a horizontal mobility PL-1C of Experimental Example 1. FIG. 10B shows a plot PL-2A when a drain-source voltage is 5.1 V, a plot PL-2B when the drain-source voltage is 0.1 V, and a horizontal mobility PL-2C of Experimental Example 2. FIG. 10C shows a plot PL-3A when a drain-source voltage is 5.1 V, a plot PL-3B when the drain-source voltage is 0.1 V, and a horizontal mobility PL-3C of Experimental Example 3. FIG. 10D shows a plot PL-4A when a drain-source voltage is 5.1 V, a plot PL-4B when the drain-source voltage is 0.1 V, and a horizontal mobility PL-4C of Experimental Example 4. FIG. 10E shows a plot PL-5A when a drain-source voltage is 5.1 V, a plot PL-5B when the drain-source voltage is 0.1 V, and a horizontal mobility PL-5C of Experimental Example 5.

Referring to Table 2 and FIGS. 10A to 10E, it is shown that mobility (μFE) of Experimental Examples 1 to 5 increase in order. That is, it may be seen that, in the semiconductor pattern containing the indium gallium tin zinc oxide, tin plays a role in boosting charge mobility of the channel area. Referring to FIGS. 10A to 10E, it may be seen that mobility in FIGS. 10A and 10B have generally similar forms, whereas mobility in FIGS. 10C to 10E have plot forms with predetermined peaks. Accordingly, the semiconductor pattern SP according to the present disclosure may have a tin composition ratio corresponding to Experimental Example 3, that is, a tin content ratio of at least 18 in the indium gallium zinc tin oxide.

In one example, referring to Table 2, it appears that Experimental Examples 1 to 5 have the subthreshold swing (SS) values increasing in order. In addition, it appears that Experimental Examples 1 to 5 have the defect densities (Dit) increasing in order. That is, it may be seen that, as the tin content increases in the semiconductor pattern containing the indium gallium tin zinc oxide, the subthreshold swing (SS) also increases, and accordingly, a density (a trap density) of charges trapped in the channel area increases.

The semiconductor pattern SP according to the present disclosure may contain the indium gallium zinc tin oxide having a composition ratio of approximately In:Ga:Zn:Sn=29.4:39.8:12.6:18.2 (at. %). According to the present disclosure, as the content ratio of tin in the semiconductor pattern SP is controlled, the trap density is not excessively increased while the charge mobility is increased, so that the semiconductor pattern SP with the improved electrical characteristics may be provided.

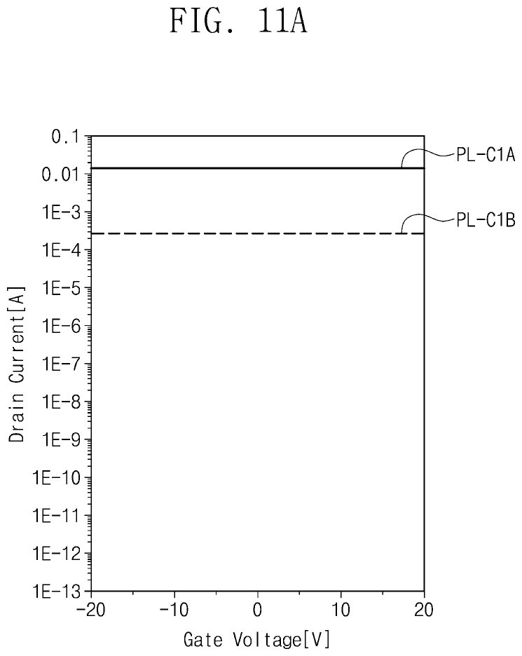

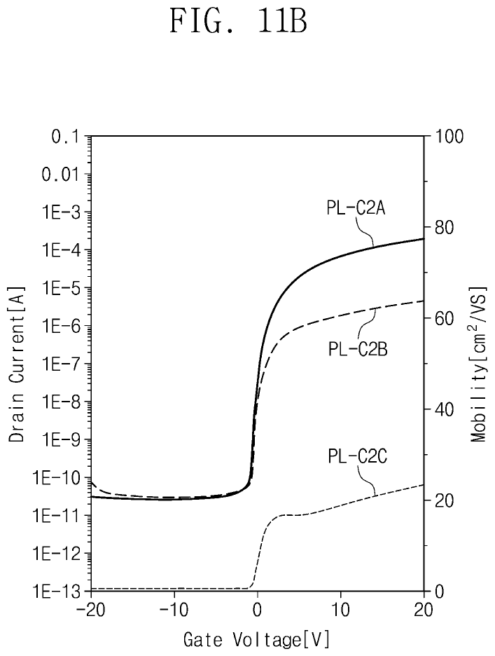

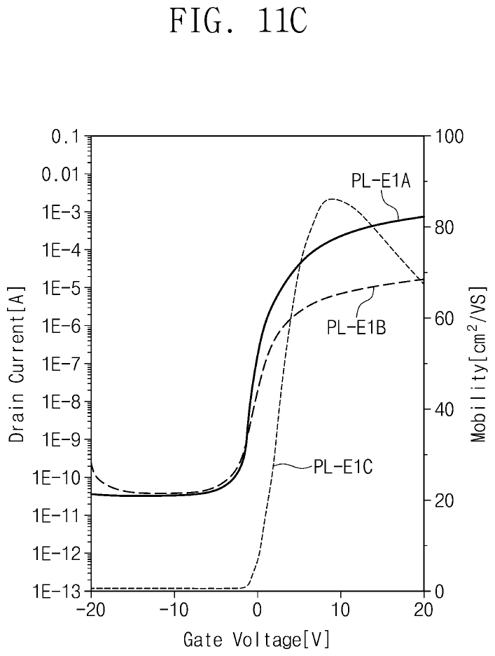

FIGS. 11A to 11C are graphs showing electrical characteristics of Present Example of the present disclosure and Comparative Examples. Each of FIGS. 11A to 11C shows a change in a drain current change and a change in mobility based on a gate voltage. Hereinafter, the present disclosure will be described with reference to Table 2 and FIGS. 11A to 11C.

TABLE 3

| | Horizontal | Saturation | Subthreshold | Threshold |
|---|---|---|---|---|
| | mobility | mobility | swing (SS, | voltage |
| Temperature | (μ_{Lin}, cm²/Vs) | (μ_{Sat}, cm²/Vs) | V/decade) | (V_{TH}, V) |
| 300° C. | — | — | — | — |
| 400° C. | 85.91 | 52.93 | 0.328 | −0.494 |
| 500° C. | 23.27 | 14.35 | 0.203 | −0.146 |

Table 3 compares electrical characteristics of the semiconductor pattern SP based on the heat treatment temperature. FIG. 11A shows a change in a drain current and a change in mobility based on a gate voltage of a semiconductor pattern (hereinafter, Comparative Example 4) subjected to heat treatment at 300° C., FIG. 11B shows a change in a drain current and a change in mobility based on a gate voltage of a semiconductor pattern (hereinafter, Comparative Example 5) subjected to heat treatment at 500° C., and FIG. 11C shows a change in a drain current and a change in mobility based on a gate voltage of a semiconductor pattern (hereinafter, Present Example 2) subjected to heat treatment at 400° C. FIGS. 11A to 11C show plots PL-C1A, PL-C2A, and PL-E1A when a drain-source voltage is 5.1 V and plots PL-C1B, PL-C2B, and PL-E1B when the drain-source voltage is 0.1 V, and horizontal mobility PL-C2C, and PL-E1C, respectively.

Referring to Table 3 and FIG. 11A, in Comparative Example 4, the horizontal mobility, the saturation mobility, the subthreshold swing, and the threshold voltage are not measured. It may be seen that the constant drain current appears regardless of the gate voltage. That is, it appears that Comparative Example 4 has a substantially conductor like tendency. The heat treatment temperature of 300° C. is relatively low, making it difficult for hydrogen atoms present in the second insulating layer IL2 to diffuse after migrating into the channel area. Accordingly, a concentration of the hydrogen atoms in the channel area of Comparative Example 4 becomes relatively high. Because the hydrogen atoms act as carriers in the semiconductor pattern, it may appear that the electrical characteristics of Comparative Example 4 have the substantially conductor like tendency. Therefore, the horizontal mobility of Comparative Example 4 is not shown.

Referring to Table 3 and FIGS. 11B and 11C, Present Example 2 may have the horizontal mobility (μLin) and the saturation mobility (μSat) higher than those of Comparative Example 5. The semiconductor pattern according to the present disclosure may have the horizontal mobility and the saturation mobility equal to or greater than about 30 cm²/Vs. In the present embodiment, it was measured that Present Example 2 has the horizontal mobility of 85.91 cm²/Vs and the saturation mobility of 52.93 cm²/Vs. In addition, it appears that Present Example 2 has the subthreshold swing greater than that of Comparative Example 5.

It appears that Comparative Example 5 has electrical characteristics substantially corresponding to the semiconductor pattern before the insulating layer is formed, that is, the first initial semiconductor pattern SP-I1. It may be seen that, in Comparative Example 5, which was heat-treated at the high temperature, the mobility is lowered compared to that in Present Example 2. In Comparative Example 5, as the hydrogen atoms diffused from the insulating layer IL2 to the channel area because of the high-temperature heat treatment diffuse to a periphery of the channel area, the number of hydrogen atoms remaining in the channel area may be reduced compared to that in Present Example 2. Accordingly, Comparative Example 5 may be substantially less affected by the hydrogen atoms than Present Example 2. A detailed description thereof will be described later.

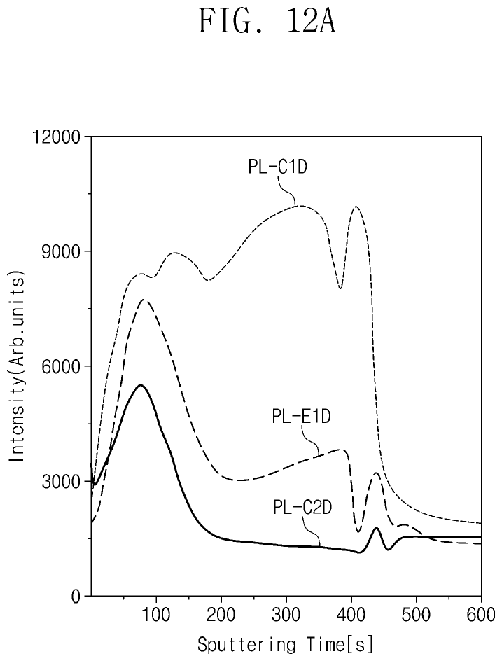

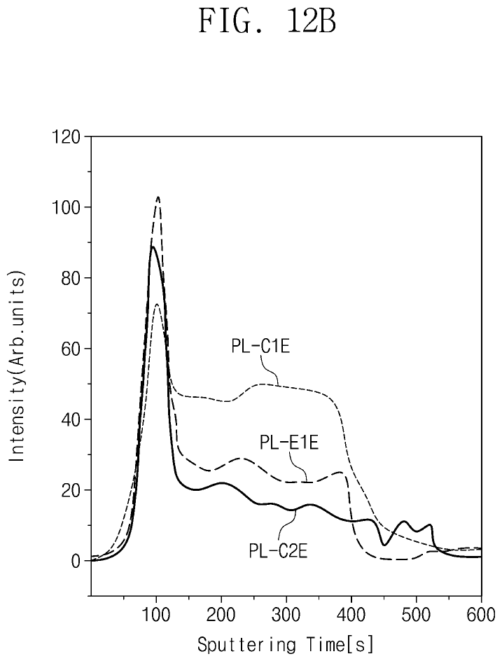

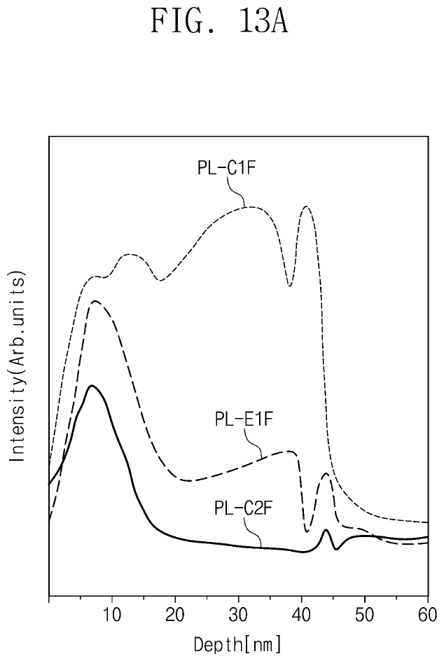

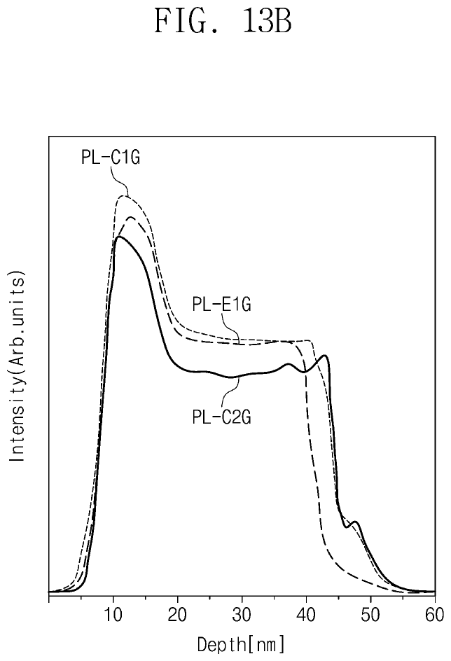

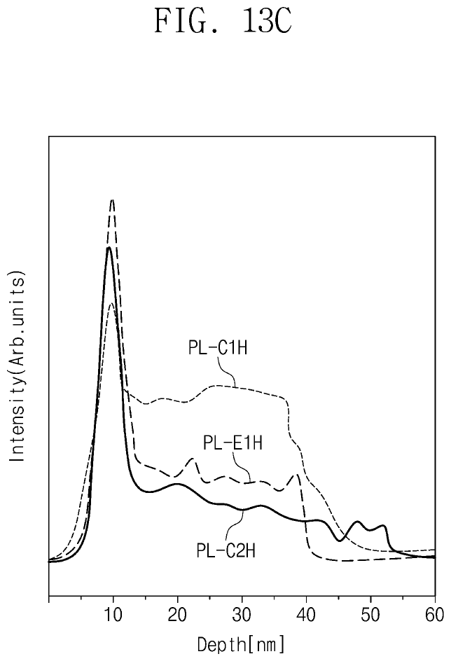

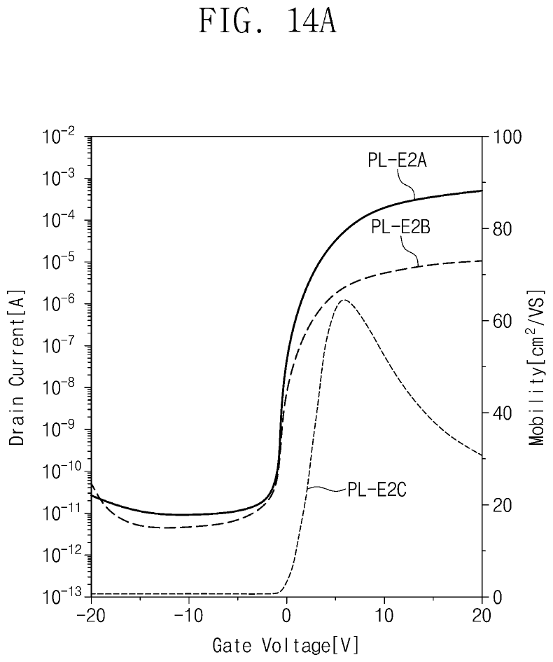

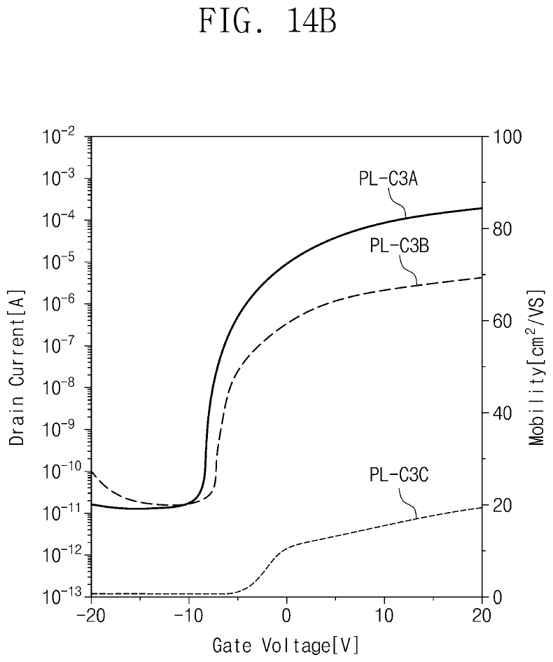

FIGS. 12A and 12B are graphs comparing electrical characteristics of Present Example of the present disclosure and Comparative Examples. FIGS. 13A to 13C are graphs comparing electrical characteristics of Present Example of the present disclosure and Comparative Examples. FIGS. 14A and 14B are graphs comparing electrical characteristics of Present Example of the present disclosure and Comparative Examples. Hereinafter, the present disclosure will be described with reference to FIGS. 12A to 14B.

FIG. 12A shows a strength of hydrogen atoms ([H]) based on a sputtering time of each of Comparative Example 4, Present Example 2, and Comparative Example 5 described in Table 3, and FIG. 12B shows a strength of a tin-hydrogen atomic bond [SnH] based on a sputtering time of each of Comparative Example 4, Present Example 2, and Comparative Example 5. FIGS. 12A and 12B may be results obtained via time-of-flight secondary ion mass spectroscopy (TOF-SIMS), and the strength of the hydrogen atoms and the strength of the tin-hydrogen atomic bond may substantially correspond to the concentration of hydrogen atoms.

Referring to FIG. 12A, in a graph PL-CID of Comparative Example 4 that has undergone the heat treatment step at 300° C., the concentration of hydrogen atoms is high until about 400 seconds, whereas a graph PL-E1D of Present Example 2 that has undergone the heat treatment step of 400° C. and a graph PL-C2D of Comparative Example 5 undergone the heat treatment step of 500° C. show a change in the concentration of the hydrogen atoms of decreasing after a peak concentration appears before about 100 seconds. Referring to FIG. 12B, a graph PL-CIE of Comparative Example 4, a graph PL-E1E of Present Example 2, and a graph PL-C2E of Comparative Example 5 all show peak concentrations after about 100 seconds. After about 100 seconds, the relatively high concentration is maintained in the graph PL-CIE of Comparative Example 4, but the change in the concentration of decreasing to a concentration equal to or lower than 40 appears in the graph PL-E1E of Present Example 2 and the graph PL-C2E of Comparative Example 5.

That is, it may be assumed that the electrical characteristics similar to those of the conductor appear in Comparative Example 4, which has undergone the heat treatment of 300° C., as shown in FIG. 11A because the concentration of the hydrogen atoms is high when the heat treatment of 300° C. is performed as shown in FIGS. 12A and 12B. On the other hand, it may be assumed that the mobility of the device as shown in FIG. 11C is low because the concentration of the hydrogen atoms is the lowest when the heat treatment at 500° C. is performed. According to the present disclosure, the electrical characteristics of the element may be improved when performing the heat treatment at a temperature higher than 300° C. and lower than 500° C., for example, a temperature of about 400° C.

FIGS. 13A to 13C show a strength of an atomic bond based on a thickness. Graphs shown in FIGS. 13A to 13C may be result values measured for Experimental Examples with different heat treatment temperatures. Specifically, FIG. 13A shows a change in a strength of hydrogen atoms ([H]) for each of thicknesses of Comparative Example 4, Present Example 2, and Comparative Example 5 described in Table 3, FIG. 13B shows a change in a strength of an indium-hydrogen atomic bond [InH] for each of the thicknesses of Comparative Example 4, Present Example 2, and Comparative Example 5, and FIG. 13C shows a change in a strength of a tin-hydrogen atomic bond [SnH] for each of the thicknesses of Comparative Example 4, Present Example 2, and Comparative Example 5 described in Table 3. FIGS. 13A to 13C may be results obtained via the time-of-flight secondary ion mass spectroscopy (TOF-SIMS), and the strength of the hydrogen atoms, the strength of the indium-hydrogen atomic bond, and the strength of the tin-hydrogen atomic bond may substantially correspond to the concentration of the hydrogen atoms, respectively.

In one example, the sputtering time may substantially correspond to a change in the thickness. That is, as the sputtering time for forming the semiconductor pattern increases, a thickness of the formed semiconductor pattern may increase. Accordingly, the graphs of FIGS. 13A to 13C may appear similar to those of FIGS. 12A and 12B described above.

Specifically, referring to FIG. 13A, a graph PL-C1F of Comparative Example 4, which has undergone the heat treatment step of 300° C., shows a high concentration of the hydrogen atoms up to a thickness of 35 nm, whereas a graph PL-E1F of Present Example 2, which has undergone the heat treatment step of 400° C., and a graph PL-C2F of Comparative Example 5, which has undergone the heat treatment step of 500° C., show a change in the concentration of the hydrogen atoms decreasing after a peak concentration appears at a thickness of about 10 nm. This may correspond to the graph of the hydrogen strength based on the sputtering time shown in FIG. 12A.

Referring to FIG. 13C, a graph PL-C1H of Comparative Example 4, a graph PL-E1H of Present Example 2, and a graph PL-C2H of Comparative Example 5 all have peak strengths at the thickness of about 10 nm. Thereafter, a relatively high strength is maintained in the graph PL-C1H of Comparative Example 4, but a change in the strength of decreasing compared to Comparative Example 4 appear in the graph PL-E1H of Present Example 2 and the graph PL-C2H of Comparative Example 5. This may correspond to the graph of the tin-hydrogen atomic bond strength based on the sputtering time shown in FIG. 12B.

Referring to FIG. 13B, all of a graph PL-C1G of Comparative Example 4, a graph PL-E1G of Present Example 2, and a graph PL-C2G of Comparative Example 5 have peak strengths at a thickness of about 13 nm, then maintain slightly reduced strengths up to a thickness of about 40 nm, and then have changes in the strengths of rapidly decreasing.

In one example, the present disclosure will be described in more detail with reference to FIGS. 14A and 14B. FIG. 14A shows a change in a drain current and a change in mobility based on a gate voltage when an insulating layer is formed using a PEALD process, and FIG. 14B shows a change in a drain current and a change in mobility based on a gate voltage when an insulating layer is formed using a PECVD process. FIGS. 14A and 14B show plots PL-E2A and PL-C4A when a drain-source voltage is 5.1 V, plots PL-E2B and PL-C4B when the drain-source voltage is 0.1 V, and horizontal mobility PL-E2C and PL-C4C, respectively. In the present embodiment, the PEALD in FIG. 14A may be a deposition process using the aforementioned DIPAS precursor and the PECVD in FIG. 14B may be a deposition process using silane gas (SiH₄).

Referring to FIGS. 14A and 14B, it may be seen that ON-OFF characteristics based on 0 V are better and the mobility is also further improved in FIG. 14A than in FIG. 14B. That is, it may be seen that a more improved hydrogen effect has occurred in the PEALD process using the DIPAS precursor than in the PECVD process using the silane gas. It may be seen that the DIPAS precursor contains more hydrogen than the silane, and thus, applies a greater effect of hydrogen atoms to the channel area. According to the present disclosure, the DIPAS precursor concentrates the hydrogen concentration at an interface between the insulating layer containing the silicon oxide and the channel area containing the indium gallium zinc tin oxide, and the hydrogen atoms migrate into the channel area via the heat treatment process, so that the mobility of the channel area may be improved. In addition, according to the present disclosure, step coverage of the insulating layer may be improved and a monomolecular film may be easily formed using the PEALD process.

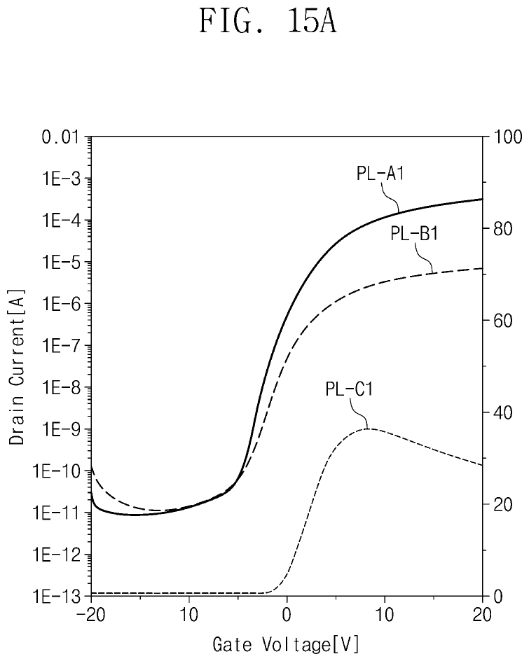

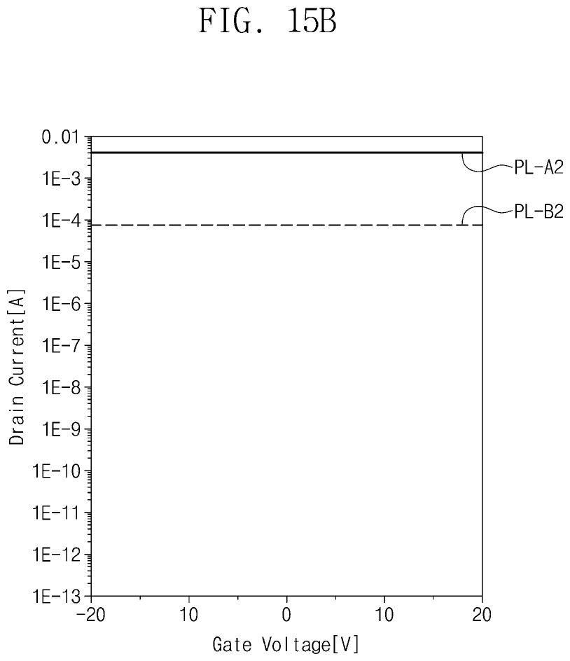

FIGS. 15A and 15B are graphs showing electrical characteristics of Present Example of the present disclosure and Comparative Examples. Each of FIGS. 15A and 15B shows a gate voltage-drain current graph. Hereinafter, the present disclosure will be described with reference to Table 3 and FIGS. 15A and 15B.

TABLE 4

| | Horizontal | Saturation | Subthreshold | Threshold |
|---|---|---|---|---|
| | mobility | mobility | swing(SS, | voltage |
| Division | (μ_{Lin}, cm²/Vs) | (μ_{Sat}, cm²/Vs) | V/decade) | (V_{TH}, V) |
| Experimental | 36.35 | 23.81 | 0.884 | −1.894 |
| Example 6 | | | | |
| Experimental | 85.91 | 52.93 | 0.328 | −0.494 |
| Example 7 | | | | |
| Experimental | — | — | — | — |
| Example 8 | | | | |

Table 4 compares electrical characteristics of the semiconductor patterns SP based on thicknesses of insulating layers covering the semiconductor patterns SP, for example, the first insulating layer 10a in FIG. 5A or the second insulating layers 20b and 20c in FIGS. 5B and 5C with each other. Experimental Example 6 may be an example covered by a silicon oxide (SiO₂) layer having a thickness of 5 nm, Experimental Example 7 may be an example covered by a silicon oxide (SiO₂) layer having a thickness of 10 nm, and Experimental Example 8 may be an example covered by a silicon oxide (SiO₂) layer having a thickness of 20 nm.

FIG. 15A illustrates a change in a drain current and a change in mobility based on a gate voltage in Experimental Example 6, and FIG. 15B illustrates a change in a drain current and a change in mobility based on a gate voltage in Experimental Example 8. FIGS. 15A and 15B show plots PL-A1 and PL-A2 when a drain-source voltage is 5.1 V, plots PL-B1 and PL-B2 when the drain-source voltage is 0.1 V, and horizontal mobility PL-C1, respectively.

Referring to Table 4 and FIGS. 15A and 15B, as the hydrogen present in the silicon oxide layer is introduced into the channel area of the semiconductor pattern by the heat treatment, the charge mobility in the channel area may be improved. When comparing Experimental Example 6 and Experimental Example 7 with each other, it appears that Experimental Example 7 having the greater thickness has higher mobility μ_{Lin} and μ_{Sat}. That is, it may be seen that, because an amount of the hydrogen present in the silicon oxide layer increases as the thickness of the silicon oxide layer covering the channel area increases, the number of hydrogen diffused into the channel area also increases.

Referring to Table 4 and FIGS. 15A and 15B, it appears that Experimental Example 8 including the silicon oxide layer having the thickness of 20 nm has the same electrical characteristics as the conductor. That is, because Experimental Example 8 has the greatest thickness among Experimental Examples 6 to 8, the greatest number of hydrogen is diffused into the channel area, which results in the semiconductor pattern substantially becoming the conductor.

According to the present disclosure, the thickness of the silicon oxide layer covering the channel area may be smaller than 20 nm and greater than 5 nm. For example, the thickness of the silicon oxide layer covering the channel area may be about 10 nm, and in this case, a semiconductor pattern having the horizontal mobility equal to or greater than 80 cm²/Vs while maintaining semiconductor properties may be formed.

Although the description has been made with reference to the preferred embodiment, those skilled in the art will understand that the present disclosure may be modified and changed in various ways without departing from the spirit and region of the present disclosure described in the following claims. Therefore, the technical scope of the present disclosure should not be limited to the contents described in the detailed description of the present document, but should be determined by the claims.

According to the present disclosure, the oxide transistor having the high mobility may be formed by controlling the composition of the oxide semiconductor and controlling the hydrogen concentration of the insulating layer in contact with the oxide semiconductor. Accordingly, the high-resolution display panel requiring a high frequency may be implemented.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a base substrate;
an organic light emitting element disposed on the base substrate;
an insulating layer disposed on the base substrate and containing silicon oxide; and
a thin film transistor disposed on the base substrate and electrically connected to the organic light emitting element,
wherein the thin film transistor includes:
a semiconductor pattern disposed on the base substrate and including a channel area in contact with the insulating layer; and
a gate electrode overlapping the channel area on a plane,
wherein the semiconductor pattern includes indium (In) gallium (Ga) zinc (Zn) tin (Sn) oxide,
wherein a ratio of tin in the channel area is equal to or higher than about 10%.

2. The display device of claim 1, wherein the channel area has a composition ratio of In:Ga:Zn:Sn=29.4:39.8:12.6:18.2 (at. %).

3. The display device of claim 1, wherein the insulating layer contains at least a portion of a DIPAS precursor.

4. The display device of claim 1, wherein the semiconductor pattern is disposed on the gate electrode.

5. The display device of claim 1, wherein the gate electrode is disposed on the semiconductor pattern,
wherein the insulating layer is disposed between the gate electrode and the semiconductor pattern.

6. The display device of claim 1, wherein a thickness of the insulating layer is greater than 5 nm and smaller than 20 nm.

7. The display device of claim 6, wherein a thickness of the insulating layer is smaller than 10 nm.

8. The display device of claim 1, wherein the channel area of the semiconductor pattern has saturation mobility equal to or greater than about 30 cm²/Vs.

9. The display device of claim 8, wherein the insulating layer contains hydrogen atoms.

10. The display device of claim 1, further comprising:
a conductive pattern connected to the semiconductor pattern,
wherein the conductive pattern is connected to a source area or a drain area spaced apart from each other with the channel area interposed.

11. A method of manufacturing a display device, the method comprising:
forming a gate electrode;
forming a semiconductor pattern including indium (In) gallium (Ga) zinc (Zn) tin (Sn) oxide obtained from indium gallium zinc oxide and tin oxide;
forming an insulating layer containing silicon oxide; and
forming an organic light emitting element on the insulating layer,
wherein the insulating layer is in contact with the semiconductor pattern,
wherein the forming of the insulating layer uses a PEALD scheme using a DIPAS precursor.

12. The method of claim 11, wherein the insulating layer is formed after the forming of the semiconductor pattern.

13. The method of claim 12, wherein mobility of the semiconductor pattern increases after the insulating layer is formed.

14. The method of claim 11, wherein the semiconductor pattern is formed after the forming of the gate electrode.

15. The method of claim 11, wherein the indium gallium zinc oxide has a composition ratio of In:Ga:Zn=1:1:1.

16. The method of claim 15, wherein the indium gallium zinc tin oxide has a composition ratio of In:Ga:Zn:Sn=29.4:39.8:12.6:18.2 (at. %).

17. The method of claim 11, further comprising:
heat-treating the insulating layer after the semiconductor pattern and the insulating layer are formed,
wherein a heat treatment temperature is higher than 300° C. and lower than 500° C.

18. The method of claim 17, wherein the heat treatment temperature is about 400° C.

19. The method of claim 18, wherein the insulating layer contains at least a portion of the DIPAS precursor.

20. The method of claim 19, wherein a concentration of hydrogen atoms at an interface of the insulating layer in contact with the semiconductor pattern is reduced after the heat-treating of the insulating layer.
